(19) United States
(12) Patent Application Publication
(10) Pub. No.: US 2025/0020729 A1
(43) Pub. Date: Jan. 16, 2025

(54) DETECTION METHOD AND DEVICE FOR ENERGY STORAGE DEVICES

(71) Applicant: JINAN UNIVERSITY, Guangzhou (CN)

(72) Inventors: Tuan GUO, Guangzhou (CN); Qingsong WANG, Guangzhou (CN); Wenxin MEI, Guangzhou (CN); Xiaobin XUE, Guangzhou (CN); Zhi LIU, Guangzhou (CN); Xile HAN, Guangzhou (CN); Gaozhi XIAO, Guangzhou (CN)

(73) Assignee: JINAN UNIVERSITY, Guangzhou, GD (CN)

(21) Appl. No.: 18/768,343

(22) Filed: Jul. 10, 2024

(30) Foreign Application Priority Data
Jul. 10, 2023 (CN) 202310843450.6

(51) Int. Cl. G01R 31/392; G01K 13/00; G01L 11/02; G01R 31/382; G08B 21/18; H01M 10/42

(52) U.S. Cl. CPC G01R 31/392; G01K 13/00; G01L 11/025; G01R 31/382; G08B 21/185; H01M 10/4285; H01M 2200/10; H01M 2200/20

(57) ABSTRACT

A method for detecting a state of an energy storage device (e.g. lithium-ion battery) is provided, which includes acquiring at least one of a change signal of a temperature or a change signal of a pressure inside the energy storage device, and determining the state of the energy storage device based thereon. The method may further include triggering a warning when the state of the energy storage device meets a preset condition, such as when the energy storage device is determined to be in an irreversible state, an internal short circuit state, a safety valve opening state, or a thermal runaway state. A detection device implementing the detection method is also provided, which comprises a sensing module and an analyzing module. The sensing module is arranged at an interior position of the energy storage device, and can include an optical sensor and/or an electrical sensor.

### CROSS-REFERENCE TO RELATED APPLICATION

The present application claims priority to Chinese Patent Application No. 202310843450.6 filed on Jul. 10, 2023, whose disclosure is hereby incorporated by reference in its entirety.

### TECHNICAL FIELD

This present disclosure relates to the field of energy storage devices and optical sensing, and specifically to an energy storage device detection method and device.

### BACKGROUND

The safety state of energy storage devices and the associated fire safety incidents have hindered their large-scale application in the fields of new energy vehicles and energy storage. Monitoring and early-warning technologies for the safety state of energy storage devices play a crucial role in identifying thermal runaway risks at an early stage, enabling early detection, prompt handling, and enhanced safety.

A rational and effective monitoring and early warning technology for the safety state of energy storage devices relies on the accurate acquisition of warning signals, feature extraction, and precise threshold settings. The current commonly used thermal runaway warning methods primarily include external detection (such as current, voltage, inner resistance, surface temperature, safety valve activation, smoke, and gas concentration) and internal features (such as state estimation and internal temperature). Existing safety state warnings for energy storage devices heavily depend on the selection and measurement of external signals such as electrical, thermal, acoustic, and gas measurements. The warning time from normal to abnormal state is approximately 500 seconds. However, due to the damage structure inside energy storage devices, the response speed of external electrical and thermal sensors lags behind the internal changes. Additionally, external acoustic and gas signals are significantly affected by the opening of safety valves, making it challenging to achieve early warnings for batteries with a small interval between safety valve opening and thermal runaway, as well as for large-scale energy storage devices.

Therefore, there is a need for the development and innovation of implantable sensors, devices, and methods that can be non-damagingly implanted into energy storage devices to accurately acquire internal information. By rapidly obtaining information on internal pressure and temperature changes within energy storage devices, early and precise warnings of energy storage devices can be achieved.

### SUMMARY OF THE INVENTION

The purpose of the present disclosure is to provide an energy storage device detection system, method, device and a storage medium, aiming to address the issues and limitations of existing technologies in acquiring and utilizing the alteration signals (i.e. exchangeable to change signals, or variation signals) of internal temperature and pressure within energy storage devices. It is typically difficult to provide early warnings on the energy storage device, so that the safety state of the energy storage device cannot be accurately analyzed.

In one aspect, a method for detecting a state of an energy storage device is provided, which include the steps of:
(1) acquiring at least one of a change signal of a temperature or a change signal of a pressure inside the energy storage device; and
(2) determining the state of the energy storage device based on the at least one of the change signal of the temperature or the change signal of the pressure.

As used herein, and throughout other part of the disclosure as well, the term “change signal” is exchangeable to “alteration signal”, “variation signal” or alike. The temperature and pressure inside the energy storage device can also be referred to “internal temperature” and “internal pressure” of the energy storage device.

Herein, the change signal of the temperature may comprise at least one of a numerical relationship of the temperature, a derivative relationship of the temperature, or a derivative relationship between the temperature and the pressure; and the change signal of the pressure may comprise at least one of a numerical relationship of the pressure, a derivative relationship of the pressure, or a derivative relationship between the temperature and the pressure.

Herein, the energy storage device can be of any type, and can be selected from a lithium-ion battery, a solid-state battery, a lithium metal battery, a lithium-sulfur battery, a lithium-air battery, a sodium-ion battery, a zinc-ion battery, an aluminum-ion battery, a magnesium-ion battery, a potassium-ion battery, a sodium-sulfur battery, a flow battery, a liquid metal battery, a metal-air battery, a lead-acid battery, a fuel cell, a solar cell, or a supercapacitor.

Optionally, the method may further comprise a step of:
(3) triggering a warning when the state of the energy storage device meets a preset condition.

According to some embodiments, the warning comprises a first warning, which is configured to be triggered when the energy storage device is determined to be in an irreversible state. Herein optionally, the energy storage device comprises a battery (e.g. lithium-ion battery, a solid-state battery, a lithium metal battery, a lithium-sulfur battery, a lithium-air battery, a sodium-ion battery, a zinc-ion battery, an aluminum-ion battery, a magnesium-ion battery, a potassium-ion battery, a sodium-sulfur battery, a flow battery, a liquid metal battery, a metal-air battery, a lead-acid battery, etc.), and the irreversible state comprises at least one of solid electrolyte interface (SEI) decomposition, separator melting, electrode-electrolyte reaction, electrode-binder reaction, or electrolyte decomposition.

Optionally, the first warning is determined based on at least one of a derivative relationship of the temperature or a derivative relationship of the pressure. Further optionally, the first warning is determined based on at least one of the occurrence of an inflection point in a derivative of the temperature (i.e. time derivative of the temperature) or the occurrence of an inflection point in a derivative of the pressure (i.e. time derivative of the pressure).

According to some embodiments, the warning further comprises a second warning, configured to be triggered when the energy storage device is determined to be in an internal short circuit state and/or a safety valve opening state. Herein, the internal short circuit state comprises at least one of separator melting, contact between positive and negative electrodes, or voltage drop; and the safety valve opening state comprises at least one of gas release, pressure increase, or mass loss. Optionally, the second warning is triggered when at least one of the following is met: the temperature suddenly jumps; or the pressure suddenly drops after reaching a maximum value.

According to some embodiments, the warning further comprises a third warning, configured to be triggered when the energy storage device is determined to be in a thermal runaway state. Herein, the thermal runaway state comprises at least one of continuous temperature rise, gas release, the emergence of a second pressure peak, combustion, or explosion. Optionally, the third warning is triggered when the temperature continues to rise while the pressure first increases and then decreases.

According to some embodiments provided by this present disclosure, the method is implemented by means of a detection device, which comprises a sensing module and an analyzing module. The step (1) of acquiring at least one of a change signal of a temperature or a change signal of a pressure inside the energy storage device is by means of the sensing model; and the step (2) of determining the state of the energy storage device is by means of the analyzing module.

Optionally, the sensing module comprises at least one of an optical sensor or an electrical sensor. Further optionally, the optical sensor comprises an optical chip and/or a fiber sensor, wherein the fiber sensor comprises one or more of a tilted fiber Bragg grating, a fiber Bragg grating, a long-period fiber grating, a fiber core diameter mismatch device, a fiber core misalignment device, a tapered fiber device, a micro/nano fiber device, a Fabry-Perot fiber device, a single/multi-mode fiber structure device, a photonic crystal fiber device, a microstructure fiber device, a polymer fiber device, a sapphire optical device, a fiber laser device, a fiber coupling device, or a self-assembled optical device; and the electrical sensor comprises one or more of a thermistor, a thermocouple, a thermal capacitor, a nano temperature sensor, an infrared temperature sensor, a piezoresistive sensor, a piezoelectric sensor, a piezoelectric ceramic sensor, a piezoelectric acoustic wave sensor, a piezoelectric resonance sensor, a pressure wire sensor, or a capacitive sensor. According to some embodiments, the fiber sensor comprises a fiber Bragg grating and a Fabry-Perot fiber device.

Further optionally, the sensing module is arranged at an interior position of the energy storage device, and the interior position may comprise one or more of an internal gap position, an electrode position, a separator position, an electrolyte position, and a tab position; herein the internal gap position comprises one or more of a cell hole position, a cell top cover position, and a cell shell inner side position.

According to some embodiments of the method, the state of the energy storage device may comprise at least one of a state of health (SOH), a state of charge (SOC), or a safety lifespan.

In another aspect, the present disclosure further provides an energy storage device detection device, which substantially implements the method as described above.

The detection device includes a sensing module and an analyzing module. The sensing module is placed inside an energy storage device and is configured to acquire the internal temperature and the internal pressure of the energy storage device and to transmit them to the analyzing module. The analyzing module is configured to evaluate the state of the energy storage device by analyzing the alteration signals of the internal temperature and/or of the internal pressure.

According to some embodiments of the detection device, the alteration signals of the internal temperature include at least one of a numerical relationship of the temperature, a derivative relationship of the temperature, or a derivative relationship between the temperature and the pressure; and the alteration signals of the internal pressure include at least one of a numerical relationship of the pressure, a derivative relationship of the pressure, or a derivative relationship between the temperature and the pressure.

As used herein, the “derivative relationship of the pressure” refers to a rate of increase (i.e. a rise rate or increase rate) of the internal pressure, the “derivative relationship of the temperature” refers to a rate of increase (i.e. a rise rate or increase rate) of the internal temperature, the “numerical relationship of the pressure” refers to a change of the internal pressure over time, and the “numerical relationship of the temperature” refers to a change of the internal temperature over time.

According to some embodiments of the detection device, the analyzing module provides an early warning by analyzing the alteration signals of the internal temperature and/or the internal pressure.

According to some embodiments of the detection device, the early warning comprises a first early warning, which is triggered when the energy storage device is determined to be in an irreversible state.

As used herein, the “irreversible state” refers to a change in the capacity balance of the energy storage device (e.g. battery), which may become irreversible and may accumulate through multiple cycles, and may have a significant impact on the performance of the energy device. Therefore, it can be used as an early characteristic signal of thermal runaway in batteries. The irreversible state includes at least one of solid electrolyte interphase (SEI) decomposition, separator melting, reaction between the electrode(s) and the electrolyte, reaction between the electrode(s) and the binder (i.e. adhesive), or decomposition of the electrolyte.

According to some embodiments of the detection device, the energy storage device may comprise any one or a combination of: a lithium-ion battery, a solid-state battery, a lithium-metal battery, a lithium-sulfur battery, a lithium-air battery, a sodium-ion battery, a zinc-ion battery, an aluminum-ion battery, a magnesium-ion battery, a potassium-ion battery, and a sodium-sulfur battery, etc. The irreversible state may include at least one of solid electrolyte interphase (SEI) decomposition, separator melting, reaction between an electrode and the electrolyte, or reaction between the electrode and the binder, and decomposition of the electrolyte.

According to some embodiments of the detection device, the first early warning can be determined based on the derivative relationship of the internal temperature and/or the derivative relationship of the pressure.

According to some embodiments of the detection device, the first warning is determined based on at least one of the occurrence of an inflection point in the derivative of the internal temperature (i.e. time derivative of the internal temperature) or the occurrence of an inflection point in the derivative of the internal pressure (i.e. time derivative of the internal pressure).

The “inflection point” refers to a change in the derivative of the temperature or refers to a change in the derivative of of the pressure. For example, a change from a rise of an increasing rate of the temperature to a constant increasing rate of the temperature (i.e. constant rate of temperature rise) is defined as an inflection point in the temperature derivative, and a change from a constant increasing rate of the pressure (i.e. constant rate of pressure rise) to a rise of an increasing rate of the pressure is defined as an inflection point in the pressure derivative.

According to some embodiments of the detection device, the early warning further includes a second early warning, which is triggered when the energy storage device is determined to be in an internal short-circuit state and/or in a safety valve opening state (i.e. a state where the safety valve is open).

According to some embodiments of the detection device, the internal short-circuit state includes at least one of separator melting, contact between the positive electrode and the negative electrode, or voltage drop.

According to some embodiments of the detection device, the safety volve opening state includes at least one of gas release, pressure rise, or mass loss.

According to some embodiments of the detection device, the second warning is triggered when the internal temperature suddenly jumps and/or drops sharply after reaching a maximum value.

According to some embodiments of the detection device, the early warning further includes a third warning, which is triggered when the energy storage device is determined to be in a thermal runaway state.

According to some embodiments of the detection device, the thermal runaway state includes at least one of continuous temperature rise, gas release, occurrence of a second pressure peak, combustion, or explosion.

According to some embodiments of the detection device, the third warning is triggered when the internal temperature continuously rises and the pressure first increases and then decreases.

According to some embodiments of the detection device, the sensing module includes an optical sensor and an electrical sensor.

According to some embodiments of the detection device, the optical sensor may comprise an optical chip and/or a fiber sensor, and the fiber sensor may include one or more of a tilted fiber Bragg grating (TFBG), a fiber Bragg grating, a long period fiber grating, a fiber core diameter mismatch device, a fiber core misalignment device, a tapered fiber device, a micro/nano fiber device, a Fabry-Perot fiber device, a single/multi-mode fiber structure device, a photonic crystal fiber device, a microstructured fiber device, a polymer fiber device, a sapphire optical device, a fiber laser device, a fiber coupling device, or a self-assembled optical device.

According to some embodiments of the detection device, the electrical sensor may include one or more of a thermistor, a thermocouple, a thermal capacitor, a nano temperature sensor, an infrared temperature sensor, a piezoresistive sensor, a piezoelectric sensor, a piezoelectric ceramic sensor, a piezoelectric acoustic sensor, a piezoelectric resonant sensor, a pressure wire sensor, or a capacitive sensor.

According to some embodiments of the detection device, the fiber sensor comprises a tilted fiber Bragg grating.

According to some embodiments of the detection device, the sensing module includes a single sensor or multiple sensors, wherein the multiple sensors are connected in series or in parallel.

In embodiments where the sensing module comprises an optical sensor, it may include a reflective optical sensor and/or a transmissive optical sensor. The analyzing module comprises a light source, an optical signal analyzer, and an optical pathway connector.

The interior position of the energy storage device may include one or more of an internal gap position, an electrode position, a separator position, an electrolyte position, or a tab position. The internal gap position may include one or more of a hole position in the battery, a top cover position of the battery, or an inner side position of the battery housing.

The sensing module can be used to simultaneously measure the temperature and pressure signals inside the energy storage device, and then to transmit changes in optical signals to an analyzing module. The analyzing module can then be used to demodulate and analyze the temperature and pressure change signals to evaluate the state of the energy storage device.

In brief, each of the first warning, the second warning, and/or the third warning is associated with at least one of the following: the derivative relationship of internal pressure, the derivative relationship of internal temperature, the numerical relationship of internal pressure, the numerical relationship of internal temperature, the duration of internal temperature change, or the duration of internal pressure change.

Among them, the derivative relationship of the internal pressure refers to the rise rate of the internal pressure, and the derivative relationship of the internal temperature refers to the rise rate of the internal temperature. The numerical relationship of the internal pressure refers to the alteration of internal pressure over time, and the numerical relation of internal temperature refers to the alteration of internal temperature over time.

When the sensor is the optical sensor, it receives the varying information about the changes in the internal temperature and the pressure of the energy storage device, and transmits the change information to the analyzing module. The analyzing module performs intensity change analysis, wavelength change analysis, envelope change analysis, differential analysis, and integral analysis on the spectral signals corresponding to the optical signals, and establishes a correspondence between the state of the energy storage device and the optical signals.

The information about changes or alterations in the temperature and pressure within the energy storage device can be used to evaluate multiple parameters/variables of the internal physical states and chemical reaction processes, which may include the evaporation of electrolyte, the decomposition of solid electrolyte interphase (SEI), melting of the separator, the contact condition of the positive and negative electrodes, voltage drop, formation of internal short circuits, the opening state of safety valves, gas release, the reaction between electrodes and electrolyte, the reaction between graphite electrodes and binders, the decomposition and combustion of electrolyte, as well as the decomposition and combustion of electrodes.

Through the comprehensive optical analysis of the inside of the energy storage device by a sensor, embodiments of the present disclosure provide a detection system, method, device, and a storage medium. Based on an effective optical analysis of the internal characteristic information of the energy storage device, the working performance and service life of the energy storage device can be effectively evaluated, and early warning of potential safety hazards the energy storage device can further be provided., By analyzing the changes of in optical signals, the safety characteristics of the energy storage device can be accurately determined, thereby making it possible to make determinations on possible problems in the energy storage device.

In yet another aspect, the present disclosure further provides a computing detection device for energy storage devices. The device comprises a processor and a memory storing computer program instructions. When the processor executes the computer program instructions, the detection method as described above can be realized.

In yet another aspect, the present disclosure provides a computer-readable storage medium, on which computer program instructions are stored. When the computer program instructions are executed by a processor, the detection method as described above can be realized.

### BRIEF DESCRIPTION OF THE DRAWINGS

FIG. 1 illustrates a schematic diagram of the structure of a vehicle provided in an embodiment of the present disclosure;

FIG. 2 illustrates a schematic diagram of an energy storage power station device provided in an embodiment of the present disclosure;

FIG. 3 illustrates a schematic diagram of the energy storage enclosure provided in an embodiment of the present disclosure;

FIG. 4 shows a system schematic diagram of the battery module provided in an embodiment of the present disclosure;

FIG. 5 illustrates a schematic block diagram of the internal temperature and the internal pressure detection system in the energy storage device provided in an embodiment of the present disclosure;

FIG. 6 shows a reflective detection device for the energy storage device provided in an embodiment of the present disclosure;

FIG. 7 illustrates a transmissive detection device for the energy storage device provided in an embodiment of the present disclosure;

FIG. 8 shows the wavelength and intensity alterations of the optical signal caused by the internal temperature and the internal pressure state of the energy storage device in accordance with an embodiment of the present disclosure;

FIG. 9 depicts the change curve of the internal temperature and the internal pressure state of a battery at 100% charge state from normal condition to thermal runaway, as provided in the embodiment of the present disclosure;

FIG. 10 shows the change curve of the internal temperature and the internal pressure state of a battery at 50% charge state from normal condition to thermal runaway, as provided in the embodiment of the present disclosure;

FIG. 11 illustrates the change curve of the internal temperature and the internal pressure state of a battery at 0% charge state from a normal state to thermal runaway, as provided in the embodiment of the present disclosure;

FIG. 12 represents the three-level warning analysis curve of the energy storage device provided in the embodiment of the present disclosure;

FIG. 13 shows a schematic diagram of the inflection point of the temperature rise rate of the energy storage device provided in the embodiment of the present disclosure;

FIG. 14 shows a schematic diagram of the inflection point of the pressure rise rate of the energy storage device provided in the embodiment of the present disclosure;

FIG. 15 shows the early warning analysis curve for electrolyte evaporation in the energy storage device based on the relationship between temperature and pressure derivatives provided in the embodiment of the present disclosure;

FIG. 16 shows the analysis curve of the irreversible state of a battery at 100% charge state provided in the embodiment of the present disclosure;

FIG. 17 is the analysis curve of the irreversible state of a battery at 50% charge state provided in the embodiment of the present disclosure;

FIG. 18 shows the analysis curve of the irreversible state of a battery at 0% charge state provided in the embodiment of the present disclosure;

FIG. 19 shows the analysis curve of the internal short-circuit state of a battery at 100% charge state provided in the embodiment of the present disclosure;

FIG. 20 shows the analysis curve of the internal short-circuit state of a battery at 50% charge state provided in the embodiment of the present disclosure;

FIG. 21 shows the analysis curve of the internal short-circuit state of a battery at 0% charge state provided in the embodiment of the present disclosure;

FIG. 22 shows the analysis curve of the safety valve opening state of a battery at 100% charge state provided in the embodiment of the present disclosure;

FIG. 23 shows the analysis curve of the safety valve opening state of a battery at 50% charge state provided in the embodiment of the present disclosure;

FIG. 24 shows the analysis curve of the safety valve opening state of a battery at 0% charge state provided in the embodiment of the present disclosure;

FIG. 25 shows the analysis curve of the thermal runaway state of the energy storage device provided in the embodiment of the present disclosure;

FIG. 26 depicts the internal and external temperature change curves of the energy storage device under thermal runaway conditions provided in the embodiment of the present disclosure;

FIG. 27 illustrates a flow chart of the method for detecting the internal temperature and the internal pressure of the energy storage device provided in the embodiment of the present disclosure;

FIG. 28 shows a schematic diagram of the hardware structure of the energy storage device detection system provided in the embodiment of the present disclosure.

Legends in the Drawings: 10. Analyzing module; 101. Light Source; 102. Optical Connector; 103. Optical Signal Analyzer; 20. Energy Storage Device; 30.Sensing Module; 100. Vehicle; 1002. Battery; 1003. Controller; 1004. Motor; 200. Energy Storage Power Station Device; 300. Energy Storage Box; 3001. Energy Storage Cell; 3010. Box Body; 30101. First Part; 30102. Second Part; 30103. Accommodation Space; 40. Detection Device; 400. Battery Module; 4001. Battery Cell; 500. Energy Storage Device Detection System.

### DETAILED DESCRIPTION

In the following, description of the technical solution for certain embodiments of the present disclosure will be provided in more detail with reference to the accompanying drawings. It is to be noted that the embodiments as described herein are interpreted to constitute part, and not all, of the embodiments of the present disclosure. Based on these embodiments in the present disclosure, all other embodiments that can be obtained by people of ordinary skills in the art without involving inventive steps are interpreted to also fall within the scope of protection of the present disclosure.

It should be understood that when used in this specification and the accompanying claims, the terms “comprise”, “comprising”, “include”, “including”, and alike, are interpreted to open-ended and indicate the presence of the described features, elements, steps, operations, components, and/or combinations thereof, but do not exclude the presence or addition of one or more other features, elements, steps, operations, components, and/or combinations thereof.

It should also be understood that the terms used in this specification of the present disclosure are only for the purpose of describing specific embodiments and are not intended to impose any limitation to the present disclosure. As used in the specification and the accompanying claims, unless expressly indicated otherwise, the singular forms of “a”, “one”, and “the” are intended to include the plural forms.

It should also be further understood that the term “and/or” as used in the specification and the accompanying claims refers to any combination of one or more of the related listed items and all possible combinations, and includes these combinations.

In the embodiments of the present disclosure, the same reference numerals are used to indicate the same components. For the sake of simplicity, detailed explanations of the same components may be omitted in different embodiments. It should be understood that the thickness, length, width, and other dimensions of the various components shown in the drawings of the embodiments of the present disclosure, as well as the overall thickness, length, width, and other dimensions of integrated devices, are provided for illustrative purposes only and should not be construed as limiting the scope of the present disclosure.

The terms “a plurality of”, “multiple”, “several” or alike, as used in the present disclosure refer to two or more (including two).

The present disclosure is introduced with the application scenario of energy storage devices in vehicles, but it can also be applied to other scenarios with energy storage devices:

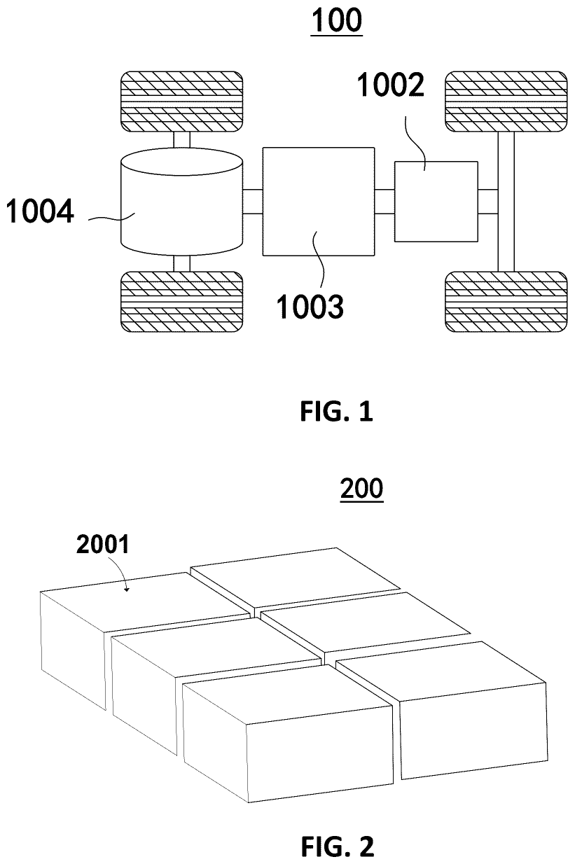

FIG. 1 illustrates a schematic diagram of a vehicle structure provided in an embodiment of the present disclosure. As shown in FIG. 1, the vehicle 100 is equipped with a battery 1002 (i.e., energy storage device), which can be installed at the bottom, front, or rear of the vehicle 100. The battery 1002 can be used to power the vehicle 100, for instance, as an operating power source of the vehicle 100.

The vehicle 100 further includes a controller 1003 and a motor 1004. The controller 1003 is used to control the battery 1002 to supply power to the motor 1004, for example, to meet the power demands during the startup, navigation, and driving of the vehicle 100.

In some embodiments of the present disclosure, the battery 1002 may serve as the operating power source of the vehicle 100, but may also serve as a driving power source, which may replace or partially replace fuel (e.g. gas, diesel, natural gas, etc.) to provide driving power for the vehicle 100.

FIG. 2 illustrates a schematic diagram of an energy storage power station device provided in an embodiment of the present disclosure. As shown in FIG. 2, the energy storage power station device 200 includes, and is designed to accommodate, multiple energy storage boxes 300, and the multiple energy storage boxes 300 may be connected in series and/or parallel to collectively form the energy storage power station device 200. Among them, the number of series connections is determined based on the terminal voltage design requirements of the energy storage boxes 300, while the number of parallel connections is determined by factors such as the capacity design requirements, redundancy, and operating mode of the energy storage power station device 200.

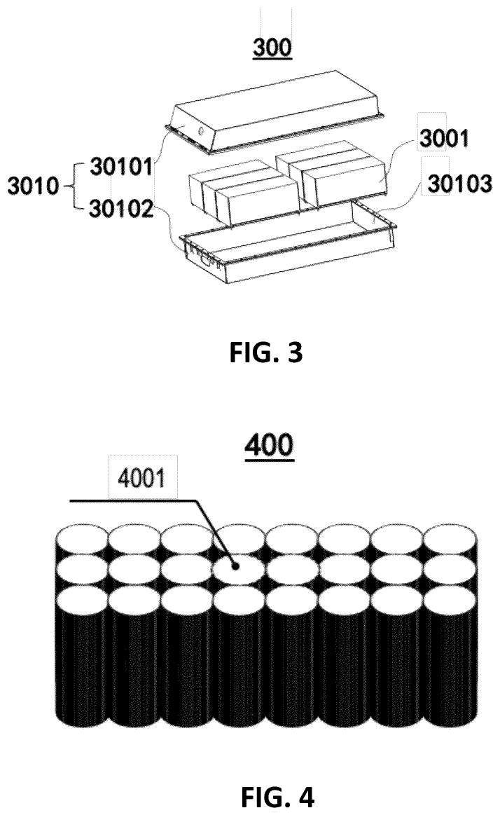

FIG. 3 is a schematic diagram of an energy storage box provided in an embodiment of the present disclosure. As shown in FIG. 3, the energy storage box 300 includes a box body 3010 and an energy storage battery module. The energy storage battery module comprises at least one energy storage cell 3001, and the energy storage battery module is contained within the box body 3010.

The box body 3010 is used to accommodate the energy storage battery cells, and it may have various different structures. In some embodiments, the box body 3010 includes a first part 30101 and a second part 30102. The first part 30101 and the second part 30102 are mutually engaged, and together they define a containment space 30103 for accommodating the energy storage battery cells. The second part 30102 can be a hollow structure with one end open, while the first part 30101 is a plate-shaped structure that covers the open side of the second part 30102, forming the box body 3010 with the accommodation space 30103. Alternatively, both the first part 30101 and the second part 30102 can have a hollow structure with one side open, and the open side of the first part 30101 covers the open side of the second part 30102, forming the box body 3010 with the accommodation space 30103. It should be noted that the first part 30101 and the second part 30102 can have various shapes, such as cylindrical or rectangular, etc.

To improve the sealing performance after the connection between the first part 30101 and the second part 30102, a sealing means such as a sealant or a sealing rings can be placed between the first part 30101 and the second part 30102.

Assuming that the first part 30101 covers the top of the second part 30102, the first part 30101 can also be referred to as the upper cover, and the second part 30102 can also be referred to as the lower box.

In the energy storage box 300, there can be one or more than one energy storage cell 3001. If there are multiple (i.e. more than one) energy storage cells 3001, they can be connected in series, in parallel, or a combination of both. The combination refers to a configuration where some of the energy storage cells 3001 are connected in series while others are connected in parallel. Multiple energy storage cells 3001 can be directly connected in series, parallel, or a combination of both, and then housed as a whole in the box body 3010. Alternatively, the multiple energy storage cells 3001 can first be connected in series, parallel, or a combination of both to form energy storage modules, and then these energy storage modules can be connected in series, parallel, or a combination of both to form a complete assembly, which is then housed in the box body 3010.

FIG. 4 depicts a system diagram of a battery module provided in an embodiment of the present disclosure. The battery module 400 comprises a plurality of battery cells 4001. During the operation of the battery cells 4001, the temperature gradually increases, and the internal pressure also gradually rises. When the temperature of a battery cell 4001 reaches a certain level, the internal pressure also increases. At this point, the correlation between the internal temperature and the internal pressure can be used to assess the stability of the internal environment of the battery cell 4001. If the temperature and pressure of the battery cell increase to a certain level, they may puncture the separator and cause an internal short circuit in the battery cell 4001. Additionally, if the thickness of a battery cell 4001 increases to a certain extent, it can lead to deformation of the battery cell 4001 and uneven distribution of the electrolyte, which can also result in unstable operation of the battery cell 4001, triggering thermal runaway safety accidents. When a thermal runaway occurs in a battery cell 4001, it becomes a heat source, causing thermal propagation and leading to thermal runaway safety accidents in other battery cells 4001 within the battery module 400.

In summary, the energy storage device mentioned in this disclosure may include any of a battery cell, an energy storage battery pack, an energy storage box, an energy storage power stations, etc.

In the present disclosure, the battery cells can include lithium-ion rechargeable battery cells, lithium-ion primary battery cells, lithium-sulfur battery cells, sodium lithium-ion battery cells, sodium-ion battery cells, or magnesium-ion battery cells, etc. The specific embodiments of the present disclosure are not limited to these examples. The energy storage device cells can have various shapes such as cylindrical, flat, rectangular, or other shapes, and the specific embodiments of the present disclosure are also not limited to any particular shape.

The energy storage device mentioned in the embodiments of the present disclosure refers to a single physical module that includes one or more energy storage cells to provide higher voltage and capacity. For example, the energy storage device mentioned in the present disclosure can include an energy storage module or an energy storage battery pack. The energy storage device generally includes a housing that is used to encapsulate one or more energy storage cells. The housing can prevent liquids or other foreign substances from affecting the charging or discharging of the energy storage cells.

The energy storage device may comprise any one, or a combination, of the following: a lithium-ion battery, a solid-state battery, a lithium metal battery, a lithium-sulfur battery, a lithium-air battery, a sodium-ion battery, a zinc-ion battery, an aluminum-ion battery, a magnesium-ion battery, a potassium-ion battery, a sodium-sulfur battery, a flow battery, a liquid metal battery, a metal-air battery, a lead-acid battery, a fuel cell, a solar cell, or a supercapacitor. The energy storage device of the present disclosure can be used in electric vehicles, hybrid vehicles, new energy vehicles, electrochemical energy storage stations, portable electronic devices, or mobile energy storage devices.

Based on the energy storage device as described above, the present disclosure proposes an energy storage device detection system.

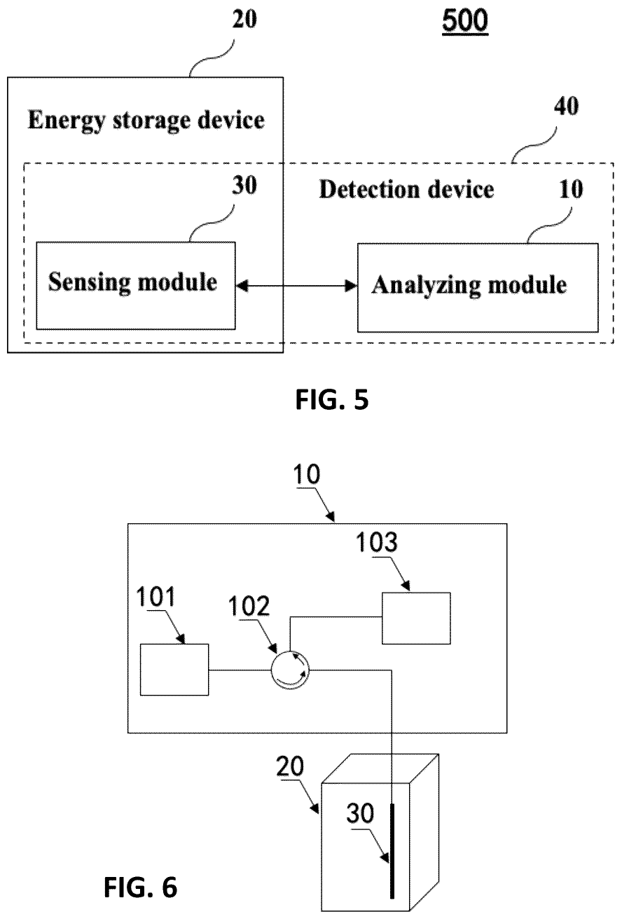

Please refer to FIG. 5, which is a schematic diagram of the energy storage device detection system provided in an embodiment of the present disclosure.

As shown in FIG. 5, the energy storage device detection system 500 comprises a detection device 40. The detection device 40 includes an analyzing module 10 and a sensing module 30, where the sensing module 30 is arranged inside an energy storage device 20. The sensing module 30 is used to acquire the internal temperature and the internal pressure of the energy storage device 20 and transmit them to the analyzing module 10. The analyzing module 10 evaluates the state of the energy storage device by analyzing the variation (or alteration, or change) signals of the internal temperature and the internal pressure.

The sensing module 30 may include any one, or a combination, of an optical sensor, an electrical sensor, an acoustic sensor, a magnetic sensor, or a mechanical sensor.

Specifically, the sensing module 30 may comprise an optical sensor that is equipped with any or a combination of Fiber Bragg Grating (FBG) and Fabry Perot (FP) interferometric structure. The temperature variations/alterations/changes induces changes in the FBG spectrum, and these changes are demodulated by the analyzing module 10 through monitoring the spectral alteration information to obtain temperature alteration information. The pressure variations/alterations/changes lead to alterations in the Fabry-Perot interference structure, which further affects the spectrum. By monitoring the spectral alteration information, the analyzing module 10 demodulates and obtains pressure alteration information. The analyzing module 10 analyzes and demodulates the optical signals from the optical sensor, which are caused by temperature and pressure changes, to obtain the spectral signal. It establishes the relationship between the spectral signal and multiple parameters inside the energy storage device 20, enabling parallel detection of multiple parameters.

Herein, the Fabry-Perot interference structure can be an open-cavity structure, a closed-cavity structure, or a structure with multiple cavities.

The optical sensor may include a single optical sensor or multiple optical sensors, and the multiple optical sensors may be connected in series or in parallel. The optical sensors can be reflective optical sensors and/or transmissive optical sensors.

The optical sensor may comprise an optical chip and/or a fiber sensor. The fiber sensor may comprise one or more of the following: tilted fiber gratings, fiber Bragg gratings, long-period fiber gratings, optical fiber core diameter mismatch devices, optical fiber core misalignment devices, tapered fiber devices, micro/nano fiber devices, Fabry-Perot (FP) fiber devices, single/multimode fiber structural devices, photonic crystal fiber devices, microstructured fiber devices, polymer fiber devices, sapphire optical devices, fiber laser devices, fiber coupling devices, and self-assembled optical devices.

Herein, in terms of modulation, the optical sensor can comprise one or more of: an intensity modulation optical fiber sensor, a polarization modulation optical fiber sensor, a phase modulation optical fiber sensor, and a frequency modulation optical fiber sensor; structurally, the optical sensor can be a dual-beam interferometer and/or a multi-beam interferometer. Herein, the dual-beam interferometer may comprise a Michelson interferometer, a Mach-Zehnde interferometer, a Sagnac interferometer or a Fizeau interferometer, and the multi-beam interferometer may comprise one or more of FP interferometers.

Herein, the electrical sensor may comprise one or more of the following: a thermistor, a thermocouple, a thermocapacitor, a nano temperature sensor, an infrared temperature sensor, a piezoresistive sensors a piezoelectric sensor, a piezoelectric ceramic sensor, a piezoelectric acoustic sensor, a piezoelectric resonance sensor, a pressure wire sensor, or a capacitive sensor.

When the energy storage device 20 is equipped with a single optical sensor, any of the above can be selected. When the energy storage device 20 is equipped with multiple optical sensors 30, including at least two optical sensors that are connected in series or parallel, the at least two optical sensors can be selected from any one or more of the above, and the connection method can be series or parallel. These optical sensors possess strong corrosion resistance and anti-interference capabilities, making them more suitable for implantation inside the energy storage device 20.

Inside the energy storage device 20, there can be one or more of the following internal locations where the sensing module 30 may be arranged: the internal gap position, the electrode position, separator position, the electrolyte position, or the tab position. Herein the internal gap position may include one or more of the following: the battery cell hole position, the battery top cover position, or the inner side of the battery casing position.

The state of the energy storage device 20 may include internal operational performance (e.g., temperature, internal pressure, interlayer expansion force, gas, dendrites, state of charge, etc.), health condition (electrolyte aging, Coulombic efficiency degradation), and safety risks (internal short circuit, internal byproducts).

In one exemplary embodiment of the present disclosure, FIG. 6 illustrates a reflectance-based detection device (or reflective detection device) for the energy storage device. The analyzing module 10 includes a light source 101, an optical signal analyzer 103, and an optical path connector 102. The light source 101 is used to emit optical signals to the optical sensor, and may comprise one or more of a laser, a broadband light source, and a supercontinuum light source.

The light source 101 emits light with an output spectrum ranging from 200 to 4000 nm.

The optical path connector 102 is used to connect the light source 101, the optical sensor, and light signal analyzer 103.The optical path connector 102 may include one or more of the following: ring resonators and couplers.

The optical signal analyzer 103 is used to receive, demodulate and process one or more of the internal temperature and the internal pressure changes of the energy storage device 20 measured by the optical signal, and output optical characteristic information.

In this embodiment, by placing the optical sensor inside the energy storage device 20, the optical signal from a specific position inside the energy storage device 20 is captured. This allows for analyzing the changes in internal temperature and internal pressure, specifically, conducting in-depth analysis of the spectral signal to accurately determine the electrode and electrochemical characteristics of the energy storage device 20, so as to analyze and evaluate the state of the energy storage device 20.

The following is a specific introduction to the analyzing module 10 in the present disclosure:

[symbol]

In one embodiment, as shown in FIG. 6, the analyzing module 10 can include light source 101, optical connector 102, and optical signal analyzer 103.

Here, the optical sensor is taken as an example of an optical fiber sensor, specifically a reflective optical fiber sensor, for illustration purposes.

The light source 101 is used to provide optical signals to the optical sensor.

The optical sensor simultaneously measures the temperature and pressure changes signals inside the energy storage device 20 and transmits these signals through the optical path connector 102 to the analyzing module 10.

The optical signal analyzer 103 in the analyzing module 10 acquires the real-time temperature and pressure change signals from the internal of the energy storage device 20. Based on the results of the change signals, it assesses the safety performance of the energy storage device 20.

Specifically, the analyzing module 10 operates as follows: the light source 101 provides optical signals to the optical sensor, and the optical sensor acquires in real-time the change signals of temperature and pressure inside the energy storage device 20. The optical sensor reflects the optical signals to the optical signal analyzer 103, and the optical signal analyzer 103 demodulates and analyzes the received optical signals to evaluate the safety performance of the energy storage device 20.

In this embodiment, the optical coupler 102 is exemplified by a circulator. The circulator has three ports: the first port is connected to the light source 101, the second port is connected to the optical sensor, and the third port is connected to the optical signal analyzer 103.

Specifically, the working process of the analyzing module 10 is as follows: The light source 101 transmits the optical signal to the first port of the circulator. The signal propagates from the first port to the second port, where it is provided to the optical sensor. The optical sensor receives the optical signal carrying the temperature and pressure change information inside the energy storage device 20. The optical sensor reflects the optical signals back to the second port, and the signals then propagate from the second port to the third port. The optical signal analyzer 103 demodulates and analyzes the received optical signals to evaluate the safety performance of the energy storage device 20.

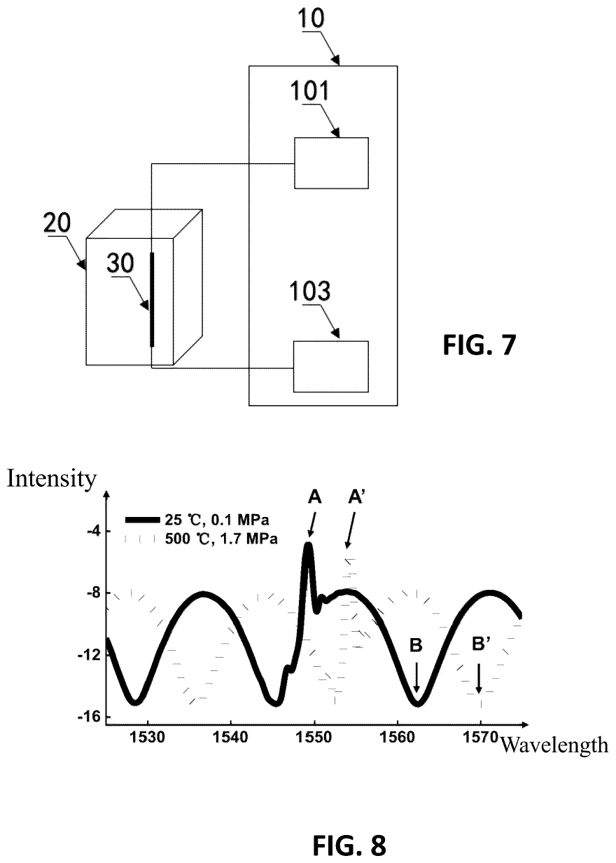

In another embodiment, as shown in FIG. 7, a transmissive detection device for the energy storage device is provided in an embodiment of the present disclosure. The analyzing module 10 includes a light source 101 and a light signal analyzer 103.

The light source 101, optical sensor, and light signal analyzer 103 are connected in sequence. In this case, the optical sensor is a transmissive optical fiber sensor.

The light source 101 is used to provide optical signals to the optical sensor.

The optical sensor simultaneously measures the temperature and pressure changes within the energy storage device 20 and transmits the temperature and pressure change signals from the energy storage device 20 to the analyzing module 10.

The optical signal analyzer 103 in the analyzing module 10 acquires the real-time temperature and pressure change signals from the internal of the energy storage device 20, and evaluates the state of the energy storage device 20 based on the results of the change signals.

Specifically, the analyzing module 10 operates as follows: the light source 101 provides an optical signal to the optical sensor. The optical sensor 30 captures real-time temperature and pressure changes from the internal of the energy storage device 20. The optical sensor transmits the optical signals to the optical signal analyzer 103, and the analyzer demodulates and analyzes the received optical signals to evaluate the state of the energy storage device 20.

The demodulation and analysis of the received optical signal specifically includes the analysis of the wavelength and intensity change curve of the optical signal caused by the internal temperature and the internal pressure state of the energy storage device, the change curves of internal temperature and pressure states from normal state to thermal runaway for batteries in different charging states, the three-level early warning analysis curve of the energy storage device, the schematic diagram of inflection point of temperature rise rate (i.e. time derivative of temperature or the derivative of temperature) of the energy storage device, the schematic diagram of inflection point of pressure rise rate (i.e. time derivative of pressure or the derivative of pressure) of the energy storage device, the warning analysis curve of the electrolyte evaporation in the energy storage device based on the derivative relationship between temperature and pressure, the irreversible state analysis curve of batteries in different charging states, the internal short-circuit state analysis curve of batteries in different charging states, the safety valve opening state analysis curve of batteries in different charging states, the thermal runaway state analysis curve of the energy storage device, the change curves of internal and external temperatures during thermal runaway of the energy storage device, etc. This process aims to establish the relationship between the change signals of temperature and pressure and the state of the energy storage device. In short, the change signals of internal temperature include at least one of the numerical relationship of temperature, the derivative relationship of temperature, or the derivative relationship between temperature and pressure; while the change signals of internal pressure include at least one of the numerical relationship of pressure, the derivative relationship of pressure, or the derivative relationship between temperature and pressure.

The analyzing module 10 can be further configured to providethe first warning, second warning, and third warning. The first warning is used to determine the irreversible state of the energy storage device 20, the second warning is used to determine the internal short circuit and/or the safety valve opening state of the energy storage device 20, and the third warning is used to determine the thermal runaway state of the energy storage device 20.

This embodiment further includes: acquiring the spectral signal corresponding to the change signal; conducting intensity change analysis, wavelength change analysis, envelope change analysis, differential analysis, and integral analysis on the spectral signal; and establishing an optical correspondence relationship with relevant parameters of the energy storage device's state.

FIG. 8 shows the wavelength and intensity alteration curves of optical signals caused by the internal temperature and internal pressure states of an energy storage device in an embodiment of the present disclosure. The optical sensor is placed inside the energy storage device 20 for monitoring the internal temperature and internal pressure state of the energy storage device 20 to evaluate its state. The energy storage device 20 includes different media such as solid, liquid, and gas, and the response of optical signals to different temperatures and pressures inside the energy storage device 20 is mainly reflected in the spectral signal, specifically in the differences in spectral signal intensity and spectral signal wavelength. By establishing a response function between different temperatures and pressures inside the energy storage device 20 and optical spectral signals, it is possible to determine the different temperature and pressure states inside the energy storage device 20, and further monitor these states to evaluate the safety state of the energy storage device. As shown in FIG. 8, the intensity and wavelength of the optical signal received by the optical sensor placed inside the energy storage device 20 are depicted. When the battery is in a normal operating state, the wavelengths corresponding to its peak and trough are shown as A and B, respectively. However, during thermal runaway, both the temperature and pressure inside the energy storage device change, resulting in a certain degree of shift in the wavelengths corresponding to the peak and trough. It is worth noting that when only the temperature changes, the peak A drifts while the trough remains stationary; and when only the pressure changes, the trough B drifts while the peak remains stationary.

In one possible implementation, when the temperature increases from 25° C. to 500° C., the peak wavelength of the optical signal shifts by 5 nm in the direction from A to A′ (towards longer wavelengths). When the pressure increases from 0.1 MPa to 1.7 MPa, the trough wavelength of the optical signal shifts by 6.4 nm in the direction from B to B′ (towards longer wavelengths). It should be noted that the changes in internal temperature and pressure independently cause the spectral signal response and are not mutually dependent or influenced by each other.

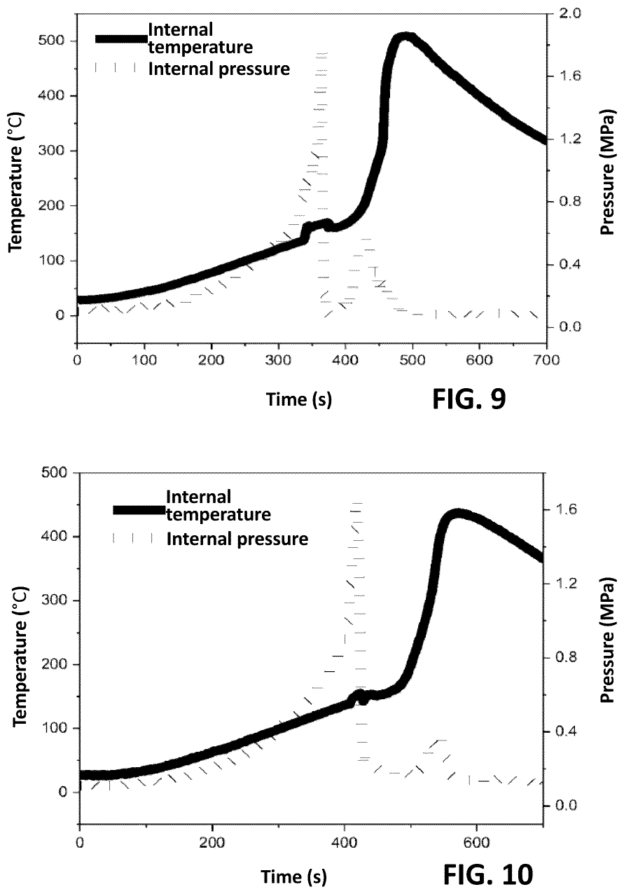

FIG. 9 depicts the alteration curves of internal temperature and internal pressure states of a 100% charged battery from a normal state to thermal runaway according to an embodiment of the present disclosure. Taking a lithium iron phosphate/graphite cylindrical 18650 battery cell with a rated capacity of 1530 mAh as an example, an optical sensor is implanted inside the battery. A heating rod with a rated power of 100 W is used to thermally abuse the battery (thermal abuse refers to a triggering method that causes thermal runaway of the battery due to continuous external heat source heating) in order to trigger thermal runaway. The heating rod is contacted and fixed with the battery implanted with the optical sensor. At the beginning of the experiment, both the heating rod and the analyzing module 10 are turned on simultaneously, where the optical signals obtained by the analyzing module 10 can be converted into temperature and pressure data in real-time. After the heater is turned on, the internal temperature of the battery rises gradually (below 70° C.), and the internal pressure remains at 0.1 MPa for more than 100 seconds, but as the temperature rises further (up to about 70° C.), the electrolyte begins to evaporate, and the internal pressure also begins to increase. Then, the solid electrolyte membrane (SEI) layer begins to decompose, and gases such as O₂, CO₂, and C₂H₄ are released successively, resulting in a significant increase in pressure. Subsequently, an internal short circuit starts, and the temperature undergoes a rapid jump of 20° C., which lasts for about 40 s, and then returns to the initial growth rate. As more and more gas is generated inside the battery, safety venting occurs, resulting in a rapid increase in internal pressure to 1.79 MPa, until the pressure exceeds the threshold of the safety valve and causes it to open. Then the gas is released quickly, leading to a sharp drop in internal pressure to 0.1 MPa (the first pressure peak). Further, the battery will undergo thermal runaway, involving an exothermic chain reaction of “anode-electrolyte-cathode” materials that begins to accumulate heat and generate gas again, resulting in a second smaller pressure peak (the second pressure peak). This is followed by the ejection of intense white smoke and a continuous increase in internal temperature, with the maximum temperature approaching 510° C.

FIG. 10 illustrates the alteration curves of internal temperature and internal pressure states of a 50% charged battery from a normal state to thermal runaway according to an embodiment of the present disclosure. Here, the energy storage device 20 takes a lithium iron phosphate/graphite cylindrical 18650 battery cell with a rated capacity of 1530 mAh as an example. An optical sensor is implanted inside the battery, and a heating rod with a rated power of 100 W is used to thermally abuse the battery to trigger thermal runaway. The heating rod is contacted and fixed with the battery implanted with the optical sensor. At the beginning of the experiment, both the heating rod and the analyzing module 10 are activated simultaneously, where the optical signals captured by the analyzing module 10 can be converted into temperature and pressure data in real-time. After the heater is turned on, the internal temperature of the battery gradually increases (below 70° C.), and the internal pressure remains at 0.1 MPa for over 110 seconds. However, as the temperature further rises (reaching about 50° C.), the evaporation of the electrolyte causes the internal pressure to also start rising. Then, the SEI layer begins to decompose, releasing gases such as O₂, CO₂, and C₂H₄, resulting in a significant increase in pressure. Subsequently, internal short circuits occur, causing a rapid temperature jump of 15° C., lasting for approximately 20 seconds, and then returns to the initial growth rate. As more and more gas is generated inside the battery, the safety venting occurs, leading to a rapid increase in internal pressure to 1.66 MPa. This continues until the pressure exceeds the threshold of the safety valve, leading to its opening. Then, the gas is rapidly released, causing the internal pressure to drop sharply to 0.1 MPa (the first pressure peak). Further, the battery will undergo thermal runaway, involving an exothermic chain reaction of “anode-electrolyte-cathode” materials that begins to accumulate heat and generate gas again, resulting in a secondary smaller pressure peak (the second pressure peak). This is accompanied by intense white smoke emission and a continuous increase in internal temperature, with the maximum temperature approaching 438° C.

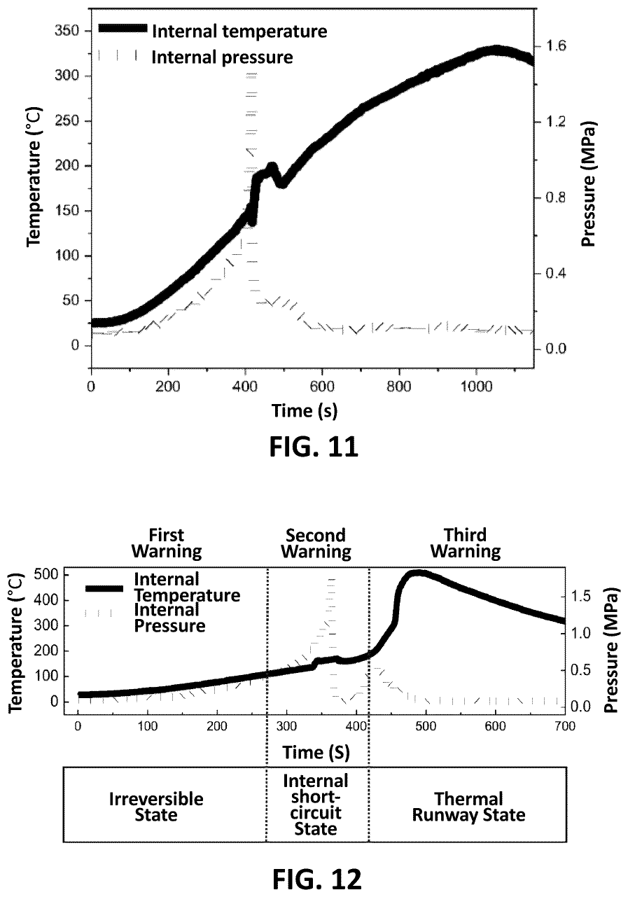

FIG. 11 depicts the alteration curves of internal temperature and internal pressure states of a 0% charged battery from a normal state to thermal runaway according to an embodiment of the present disclosure. Here, the energy storage device 20 takes a lithium iron phosphate/graphite cylindrical 18650 battery cell with a rated capacity of 1530 mAh as an example. An optical sensor is implanted inside the battery, and a heating rod with a rated power of 100 W is used to thermally abuse the battery to trigger thermal runaway. The heating rod is contacted and fixed with the battery implanted with the optical sensor. At the start of the experiment, both the heating rod and the analyzing module 10 are activated simultaneously, where the optical signals captured by the analyzing module 10 can be converted into temperature and pressure data in real-time. After the heater is turned on, the internal temperature of the battery gradually rises (below 70° C.), and the internal pressure remains at 0.1 MPa for over 120 seconds. However, as the temperature further increases (reaching approximately 50° C.), the evaporation of the electrolyte causes the internal pressure to also start rising. Then, the SEI layer begins to decompose, releasing gases consecutively, leading to a significant increase in pressure. Subsequently, internal short circuits occur, causing a rapid temperature jump of 50° C. that lasts for approximately 70 seconds, and then returns to the initial growth rate. As more and more gas is generated inside the battery, safety venting takes place, resulting in a rapid increase in internal pressure to 1.65 MPa. This continues until the pressure exceeds the threshold of the safety valve, leading to its opening. Then, rapid gas release occurs, causing the internal pressure to drop sharply to 0.1 MPa (the first pressure peak). Unlike the 100% SOC and 50% SOC batteries, due to the lack of stored internal energy, thermal runaway does not occur in the 0% SOC battery, and there is no (or at least not a significant) secondary smaller pressure peak (the second pressure peak). However, the internal temperature continues to rise, reaching a maximum temperature close to 330° C.

Furthermore, the optical sensors used in the aforementioned embodiment are employed to simultaneously acquire the internal temperature and internal pressure of the energy storage device 20 and transmit them to the analyzing module 10. The analyzing module 10 evaluates the operational performance and safety state of the energy storage device 20 by analyzing the correlation between temperature and pressure. The varying signals mentioned in these embodiments include at least one of the numerical relationships of temperature, pressure, temperature derivatives, pressure derivatives, or the derivative relationship between temperature and pressure. These signals are used to assess the state of the energy storage device 20 and set the first, second, and third warnings. The first warning is determined to indicate an irreversible state of the energy storage device 20. The second warning is determined to indicate an internal short circuit and/or the opening of the safety valve of the energy storage device 20. The third warning is determined to indicate a thermal runaway state of the energy storage device 20.

Furthermore, the derivative relationship of internal pressure refers to the rate at which the internal pressure increases. The derivative relationship of internal temperature refers to the rate at which the internal temperature increases. The numerical relationship of internal pressure refers to the changing relationship between internal pressure and time. The numerical relationship of internal temperature refers to the changing relationship between internal temperature and time.

Additionally, the alteration signals also include acquiring spectral signals corresponding to the temperature and pressure changes of the energy storage device. These spectral signals are analyzed for intensity changes, wavelength changes, envelope changes, differential analysis, and integral analysis to establish optical correlations with relevant parameters related to the state of the energy storage device.

Specifically, the alteration signals of the internal temperature and pressure of the energy storage device 20 can be used to evaluate its State of Health (SOH), State of Charge (SOC), and safety lifespan.

Specifically, the information on the temperature and pressure alterations inside the energy storage device 20 can be used to assess multiple physical quantities and chemical reactions within the device, including the evaporation of electrolyte, the decomposition of SEI layer, the melting of separator, the contact between positive and negative electrodes, voltage drop, the formation of internal short circuits, the opening state of the safety valve, gas release, the reaction between the electrode and the electrolyte, the reaction between graphite electrodes and binders, the decomposition and combustion of the electrolyte, as well as the decomposition and combustion of electrodes, and so on.

FIG. 12 depicts the three-level warning analysis curve for the energy storage device provided in the embodiment of this disclosure. The grading method for battery warnings may differ due to differences in battery types, testing methods, and evaluation criteria. However, the risk level of battery safety can be determined based on the changes in characteristic factors such as battery temperature, voltage, and gas. Specifically, in this embodiment, the optical sensor is able to precisely and simultaneously capture the change signals of internal temperature and internal pressure during the entire evolution process of battery thermal runaway, resulting in the following three warnings:

First Warning: The increase in the rate of temperature rise with no change in the rate of pressure rise serves as the start of the first warning (an alert for the evaporation of electrolyte). The end of the first warning is marked by a constant temperature rise rate accompanied by an increased pressure rise rate (an alert for the decomposition of the SEI film). Here, the turning point from an increasing temperature rise rate to a constant internal temperature rise rate is defined as the inflection point of the temperature derivative, and the transition from a constant pressure rise rate to an increased pressure rise rate is defined as the inflection point of the pressure derivative.

The physical meaning of the first warning: Within this range, it indicates that the battery has undergone the initial evaporation of electrolyte and has not yet reached the stage of SEI decomposition. No irreversible reactions have occurred during this period, ensuring that the battery can be used normally before any damage occurs.

Second Warning: A sudden jump in internal temperature (manifesting as a “wave packet” on the temperature signal) and/or a sudden drop in pressure to atmospheric pressure after reaching a maximum value serve as the start of the second warning (a signal warning for a minor internal short circuit in the battery). The rapid increase in the rate of internal temperature, along with a pressure significantly higher than atmospheric pressure, marks the end of the second warning (a warning for a severe or complete internal short circuit in the battery).

The physical meaning of the second warning: Within this range, it indicates that the battery has undergone a transition from a minor internal short circuit to a complete internal short circuit. Irreversible reactions have occurred during this period, and the warning signal is intended to be given before the battery reaches thermal runaway, providing enough escape time for passengers or operators to avoid casualties.

Third Warning: When the internal temperature continues to rise and the pressure first increases and then decreases, forming a “wave packet,” this indicates the start of thermal runaway. When the internal temperature reaches its peak and the pressure drops to atmospheric pressure, it signifies the end of thermal runaway.

The physical meaning of the third warning: Within this range, it indicates that the battery has entered a state of thermal runaway and is proceeding towards its conclusion. During this period, it is necessary to activate the corresponding fire extinguishing equipment or cut off the power supply to prevent the spread and worsening of the battery's thermal runaway, thus reducing the damage to the vehicle, equipment, or surrounding objects.

Specifically, taking a lithium iron phosphate/graphite cylindrical 18650 single cell with a rated capacity of 1530 mAh as an example:

First Warning: The gradual increase in the temperature rise rate to 0.38° C./s, with the pressure rise rate remaining below 1 kPa/s, serves as the start of the first warning (a warning for the evaporation of the electrolyte). The end of the first warning is marked by the temperature rise rate staying at 0.38° C./s while the pressure rise rate gradually increases from 1 kPa/s (a warning for the decomposition of the SEI film).

The first warning range also includes the warning for electrolyte evaporation. The conditions for determining the warning of electrolyte evaporation are as follows: the internal temperature higher than 50° C. and/or rate of pressure increase greater than 1 kPa/s for a duration of 5 seconds or more and/or internal pressure higher than 0.15 MPa.

Second Warning: A sudden jump in internal temperature of more than 10° C. (manifesting as a “wave packet” on the temperature signal) and/or a sudden drop in pressure from a value greater than 1.5 MPa to atmospheric pressure of 0.1 MPa serves as the start of the second warning (a warning for a minor internal short circuit in the battery). The rapid increase in the internal temperature rate (temperature rise rate greater than 5° C./s) along with a pressure significantly higher than atmospheric pressure marks the end of the second warning (a warning for a severe or complete internal short circuit in the battery).

The second warning also includes the warning for the open state of the pressure relief valve. The conditions for determining the warning of the open state of the pressure relief valve are as follows: internal pressure higher than 1.5 MPa; rate of pressure change less than −0.1 MPa/s or/and greater than 0.1 MPa/s.

Third Warning: A continuous rise in internal temperature (with a rate of increase equal to or greater than 1° C./s) along with a pressure value greater than 0.1 MPa, and the appearance of a “wave packet” as the pressure first increases and then decreases, indicates the start of thermal runaway. When the internal temperature reaches its peak and the pressure drops to atmospheric pressure (0.1 MPa), it signifies the end of thermal runaway.

The three warnings mentioned above can refer to specific numerical values or warning intervals. Specifically, the first warning identifies the irreversible state of the battery, representing the critical value where the battery transitions from a reversible state to an irreversible state. Irreversible states include, but are not limited to, the decomposition of the solid electrolyte interphase (SEI), separator melting, electrode-electrolyte reaction, electrode-binder reaction, and the decomposition of the electrolyte. The second warning determines the internal short-circuit state and the activation of the safety valve of the battery. The internal short-circuit state includes, but is not limited to, separator melting, contact between the positive and negative electrodes, and voltage drop. The activation of the safety valve includes, but is not limited to, gas release, pressure increase, and mass loss. The third warning assesses the thermal runaway state of the battery. Thermal runaway states include, but are not limited to, continuous temperature rise, gas release, the emergence of a second pressure peak, combustion, and explosion.

Specifically, energy storage devices may comprise any one, or a combination, of the following: a lithium-ion battery, a solid-state battery, a lithium metal battery, a lithium-sulfur battery, a lithium-air battery, a sodium-ion battery, a zinc-ion battery, an aluminum-ion battery, a magnesium-ion battery, a potassium-ion battery, a sodium-sulfur battery, a flow battery, a liquid metal battery, a metal-air battery, a lead-acid battery, a fuel cell, a solar cell, or a supercapacitor.

Specifically, energy storage devices can come in various shapes such as cylindrical, flat, rectangular, or other forms.

It is important to note that the embodiments of this disclosure have set three-level warnings based on pressure and temperature. These warnings can be set at different levels depending on the type of energy storage device, temperature characteristics, pressure characteristics, composition information, and other factors of the energy storage device.

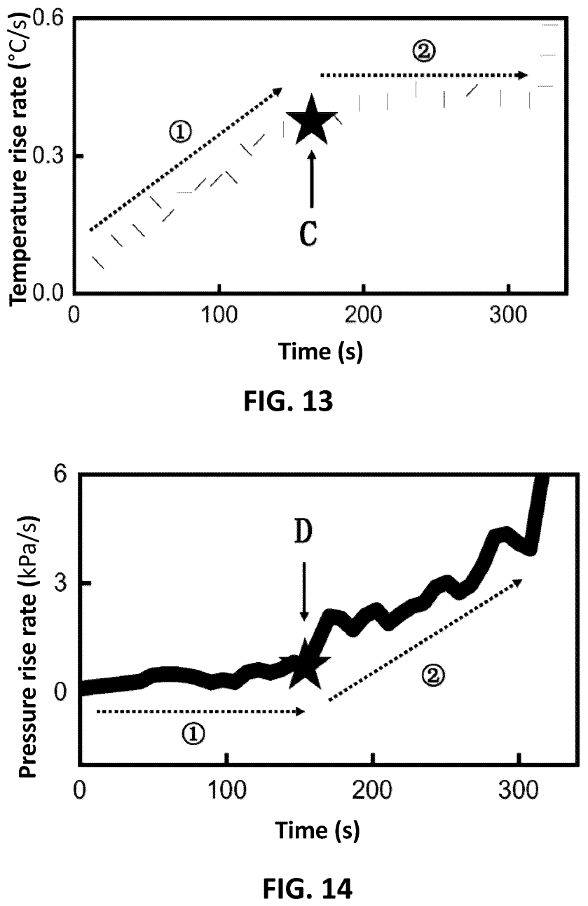

FIG. 13 is a schematic diagram of the inflection point of the temperature rise rate of the energy storage device provided in an embodiment of the present disclosure. Specifically, the energy storage device 20 takes a lithium iron phosphate/graphite cylindrical 18650 single cell with a rated capacity of 1530 mAh as an example. The single cell is in a 100% charged state. The optical sensor can accurately capture the internal temperature rise rate signal during the entire evolution process of the battery's thermal runaway state. As shown in stage \textcircled{1}, the temperature increase comes from the heat conduction of the heater, and continuous temperature rise favors the evaporation of more electrolyte. Before reaching the inflection point C, the temperature rise rate is less than 0.38° C./s, and the main changes occurring before the inflection point C are physical changes, which are reversible processes, mainly manifesting as the evaporation of the electrolyte. As shown in stage \textcircled{2}, after the inflection point C, the temperature rise rate is greater than 0.38° C./s and exhibits a relatively stable change in the temperature rise rate. Continuous temperature rise after the inflection point C can lead to the beginning of irreversible SEI decomposition. Therefore, the inflection point C detected by the optical sensor can be used as the starting signal for the irreversible state of the energy storage device. The irreversible state signal is a characteristic signal that occurs very early in the battery's thermal runaway, thus providing an extremely early safety warning for the safe use of the energy storage device.

Furthermore, energy storage devices at different states of charge (SOC) exhibit the same pattern of changes.

FIG. 14 is a schematic diagram of the inflection point of the pressure rise rate of the energy storage device provided in an embodiment of the present disclosure. Specifically, the energy storage device 20 takes a lithium iron phosphate/graphite cylindrical 18650 single cell with a rated capacity of 1530 mAh as an example, where the single cell is in a 100% charged state. The optical sensor can accurately capture the internal pressure rise rate signal during the entire evolution process of the battery's thermal runaway state. As shown in stage \textcircled{1}, the evaporation of the electrolyte caused by the temperature rise leads to changes in the internal pressure rise rate of the battery, where the pressure rise rate exhibits a relatively stable change. Before reaching the inflection point D, the pressure rise rate is less than 1 kPa/s. As shown in stage \textcircled{2}, the continuous temperature rise after the inflection point D can lead to the beginning of irreversible SEI decomposition. SEI decomposition generates a large amount of gas and rapidly increases the internal pressure of the battery, which is achieved by heat consumption and the transfer to gas. At this time, the internal pressure rise rate is greater than 1 kPa/s. The SEI decomposition represents the start of the irreversible state. Therefore, the inflection point D detected by the optical sensor can be used as the starting signal for the irreversible state of the energy storage device. The irreversible state signal is a characteristic signal that occurs very early in the battery's thermal runaway, thus providing an extremely early safety warning for the safe use of the energy storage device.

Furthermore, energy storage devices at different states of charge exhibit the same pattern of changes.

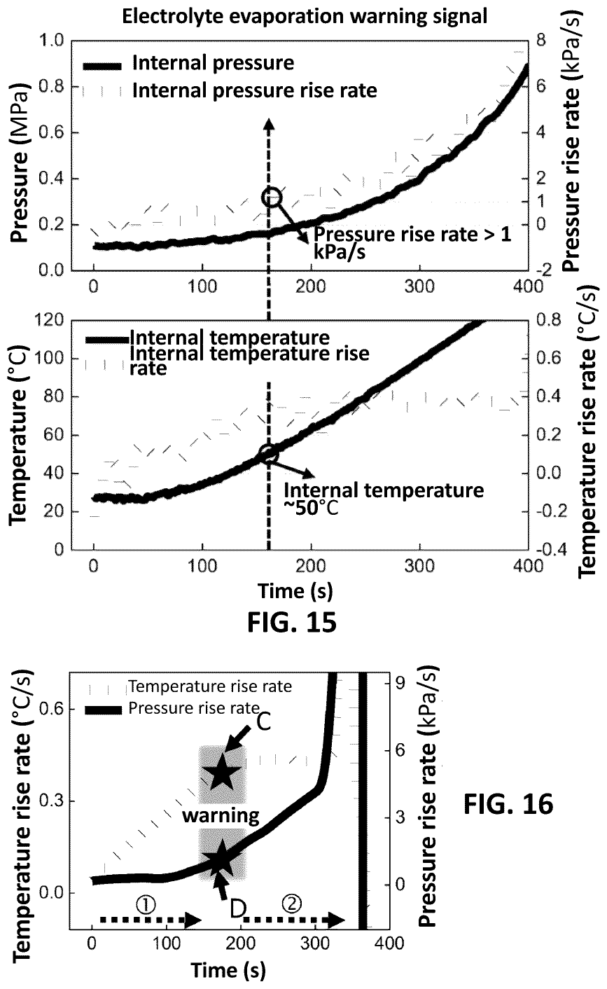

FIG. 15 depicts a curve representing the early warning analysis of electrolyte evaporation in an energy storage device based on temperature and pressure change signals, as provided in an embodiment of the present disclosure. Specifically, the energy storage device 20 takes a lithium iron phosphate/graphite cylindrical 18650 single cell with a rated capacity of 1530 mAh as an example. The optical can accurately and simultaneously capture signals of the battery's internal temperature, internal temperature rise rate, internal pressure, and internal pressure rise rate during the entire evolution process of the battery's thermal runaway state. When any of the following conditions are met: the internal temperature exceeds 50° C., the pressure rise rate exceeds 1 kPa/s and sustains for more than 5 seconds, or the internal pressure exceeds 0.15 MPa, an electrolyte evaporation warning is triggered. At this point, it is determined through the battery's temperature evolution, internal pressure evolution, and external characteristics that the battery has not undergone thermal runaway and is still within the first warning range.

Specifically, the electrolyte evaporation warning can be specified as a specific value or within a certain range.

Specifically, before the electrolyte evaporation warning is triggered, the internal pressure remains stable at around 0.1 MPa, which is near one atmosphere, and the pressure rise rate fluctuates within 0 to 1 kPa/s. However, after reaching the electrolyte evaporation warning threshold, the pressure increases significantly, with a pressure rise rate greater than 1 kPa/s. The initial increase in internal pressure caused by electrolyte evaporation indicates that only physical changes have occurred inside the battery, and no irreversible chemical changes have yet taken place. This serves as a relatively obvious early warning sign of thermal runaway and ensures the normal operation of the battery during subsequent use.

In one possible embodiment, the first warning can be determined based on the rate of change of internal temperature and/or pressure. Specifically, the corresponding “diamond-shaped” (warning zone) region appears on the temperature change rate curve and the pressure change rate curve, indicating an initial rapid temperature rise with constant pressure in the early stage, followed by accelerated pressure rise with stable temperature in the later stage. In this “warning zone,” the electrolyte evaporation intensifies for all states of charge (SOC), and the early irreversible SEI decomposition occurs at a certain temperature range (for example, around 70˜80° C.). Therefore, the first warning is set to begin from the start of electrolyte evaporation and continue through the beginning of SEI decomposition. During this range, no irreversible reactions have yet occurred, ensuring the normal use of the battery before any damage occurs.

FIG. 16 depicts the irreversible state analysis curve of a battery at 100% charge state provided in an embodiment of the present disclosure, specifically using a lithium iron phosphate/graphite cylindrical 18650 single cell with a rated capacity of 1530 mAh as an example. The first warning represents the threshold at which the battery transitions from a reversible state to an irreversible state. By associating the rate of temperature rise with the rate of pressure rise and analyzing the change signals of temperature and pressure, the first warning can be obtained. Specifically, before the first warning, the temperature increase comes from the heat conduction of the heater, leading to the evaporation of the electrolyte and an increase in internal pressure. Then, the continued temperature rise favors the production of more electrolyte vapor and the start of irreversible SEI decomposition. Consequently, the rapid generation of a large amount of gas rapidly increases the internal pressure, with the cost of heat consumption and transfer to the gas, as shown in stage \textcircled{1}. During this time, the internal pressure rise rate fluctuates within 0 to 1 kPa/s, while the temperature rise rate continues to be around 0.3° C./s. After reaching the first warning, the pressure exhibits a significant increase, with a pressure rise rate greater than 1 kPa/s. Meanwhile, the temperature rise rate remains at 0.3° C./s (as shown in \textcircled{2}). Traditional detection methods cannot obtain the irreversible state signal of the energy storage device. Therefore, the first warning detected by the optical sensor can be used as the irreversible state signal of the energy storage device. This irreversible state signal is a characteristic signal of the extremely early stage of thermal runaway in the battery, thus providing an extremely early safety warning for the safe use of the energy storage device.

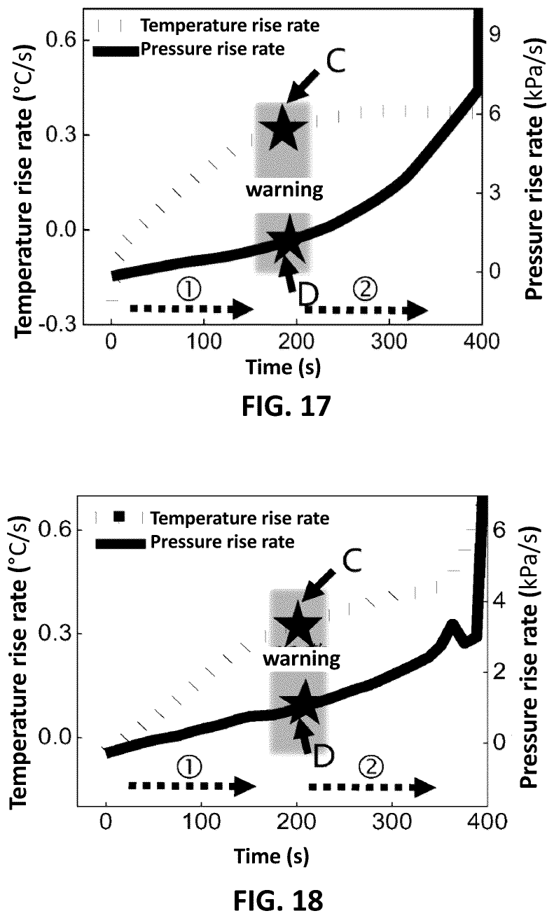

FIG. 17 presents the irreversible state analysis curve of a battery at 50% charge state provided in an embodiment of the present disclosure, specifically using a lithium iron phosphate/graphite cylindrical 18650 single cell with a rated capacity of 1530 mAh as an example. The first warning represents the threshold at which the battery transitions from a reversible state to an irreversible state. By associating the rate of temperature rise with the rate of pressure rise and analyzing the change signals of temperature and pressure, the first warning can be obtained.

Specifically, before the first warning, the temperature rises due to heat conduction from the heater, resulting in electrolyte evaporation and increased internal pressure. Then, the continued temperature rise favors the production of more electrolyte vapor and the start of irreversible SEI decomposition. Consequently, the rapid generation of a large amount of gas quickly increases the internal pressure, with the cost of heat consumption and transfer to the gas, as shown in stage \textcircled{1}. During this time, the internal pressure rise rate fluctuates within 0 to 1 kPa/s, while the temperature rise rate continues to be around 0.3° C./s. After reaching the first warning, the pressure exhibits a significant increase, with a pressure rise rate greater than 1 kPa/s. Meanwhile, the temperature rise rate remains at 0.3° C./s (as shown in \textcircled{2}). Traditional detection methods cannot obtain the irreversible state signal of the energy storage device. Therefore, the first warning detected by the optical sensor can be used as the irreversible state signal of the energy storage device. This irreversible state signal is a characteristic signal of the extremely early stage of battery thermal runaway, thus providing an extremely early safety warning for the safe use of the energy storage device.

FIG. 18 depicts the irreversible state analysis curve of a battery at 0% charge state provided in an embodiment of the present disclosure, specifically using a lithium iron phosphate/graphite cylindrical 18650 single cell with a rated capacity of 1530 mAh as an example. The first warning represents the critical value when the battery transitions from a reversible state to an irreversible state. By correlating the temperature rise rate with the pressure rise rate and analyzing the alteration signals of temperature and pressure, the first warning can be obtained. Specifically, before the first warning, the temperature increase is due to the heat conduction from the heater, leading to the evaporation of the electrolyte and an increase in internal pressure. Then, the continuous temperature rise favors the production of more electrolyte vapor and the start of irreversible SEI decomposition. Consequently, the rapid generation of a large amount of gas quickly increases the internal pressure, with the cost of heat consumption and transfer to the gas, as shown in stage \textcircled{1}. During this time, the internal pressure rise rate fluctuates within 0 to 1 kPa/s, while the temperature rise rate continues to be around 0.3° C./s. After reaching the first warning, there is a significant increase in pressure, with a pressure rise rate greater than 1 kPa/s. Meanwhile, the temperature rise rate remains at 0.3° C./s (as shown in \textcircled{2}. Traditional detection methods cannot obtain the irreversible state signal of the energy storage device. Therefore, the first warning detected by the optical sensor can be used as the irreversible state signal of the energy storage device. This irreversible state signal is a characteristic signal of the extremely early stage of battery thermal runaway, thus providing an extremely early safety warning for the safe use of the energy storage device.

In one possible embodiment, the second warning is determined as follows: a sudden jump in internal temperature by more than X (manifesting as a “wave packet” on the temperature signal) and/or a sudden drop in pressure to atmospheric pressure (0.1 MPa) after exceeding Y serves as the start of the second warning (indicating a slight internal short-circuit of the battery). The rapid increase in internal temperature rate (e.g., a temperature rise rate greater than Z) along with a pressure significantly higher than atmospheric pressure (0.1 MPa) serves as the end of the second warning (indicating a severe or complete internal short-circuit of the battery). The values of X, Y, and Z are determined based on the type of battery. For example, in a lithium iron phosphate/graphite cylindrical 18650 single cell with a rated capacity of 1530 mAh, X is 10° C., Y is 1.5 MPa, and Z is 5° C./s.

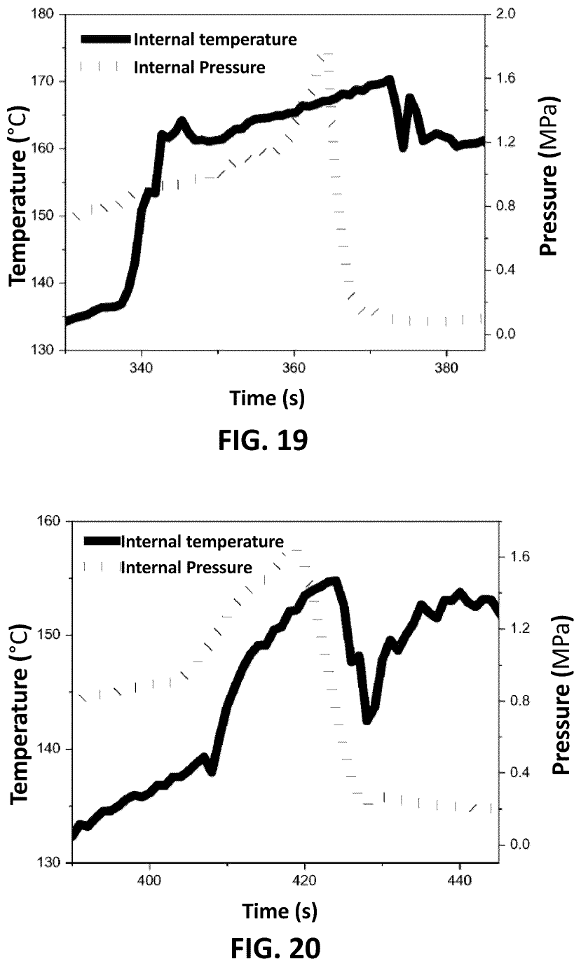

FIG. 19 depicts the analysis curve of the internal short-circuit state of a 100% charged battery provided in an embodiment of the present disclosure, specifically using a lithium iron phosphate/graphite cylindrical 18650 single cell with a rated capacity of 1530 mAh as an example. The second warning represents the critical value indicating that the battery is about to enter an internal short-circuit state. Commercially available polyethylene (PP) and polypropylene (PE) separator materials used internally in energy storage devices have melting points of approximately 165° C. and 135° C. respectively. As the temperature continues to rise, exceeding the melting point of the separator will lead to its shrinkage and decomposition, allowing the positive and negative electrode materials to come into contact with each other, resulting in an internal short-circuit. Due to the formation of the internal short-circuit, a rapid temperature rise of approximately 35° C. is detected within the energy storage device, accompanied by a gradual increase in pressure to 1.79 MPa. Subsequently, the battery's safety valve opens, causing the pressure to drop instantaneously to 0.1 MPa. By simultaneously acquiring the change information of both internal temperature and internal pressure, analyzing the correlation between temperature and pressure, and performing comprehensive analysis, the internal short-circuit state of the battery determined by the second warning can be precisely identified.

FIG. 20 shows the analysis curve of the internal short-circuit state of a 50% charged battery provided in an embodiment of the present disclosure, specifically using a lithium iron phosphate/graphite cylindrical 18650 single cell with a rated capacity of 1530 mAh as an example. The second warning indicates the critical value where the battery is about to enter an internal short-circuit state. Commercially available polyethylene (PP) and polypropylene (PE) separator materials used internally in energy storage devices have melting points of approximately 165° C. and 135° C. respectively. As the temperature continues to rise, exceeding the melting point of the separator will cause it to shrink and decompose, enabling the positive and negative electrode materials to come into contact with each other, resulting in an internal short-circuit. Due to the formation of the internal short-circuit, a rapid temperature rise is detected within the energy storage device, manifesting as a sudden temperature increase of approximately 20° C. The pressure gradually rises to 1.66 MPa, and then the battery safety valve opens, causing the pressure to drop instantaneously to 0.1 MPa. By simultaneously obtaining the change information of both internal temperature and internal pressure, analyzing the correlation between temperature and pressure, and conducting a comprehensive analysis, the internal short-circuit state of the battery determined by the second warning can be precisely identified.

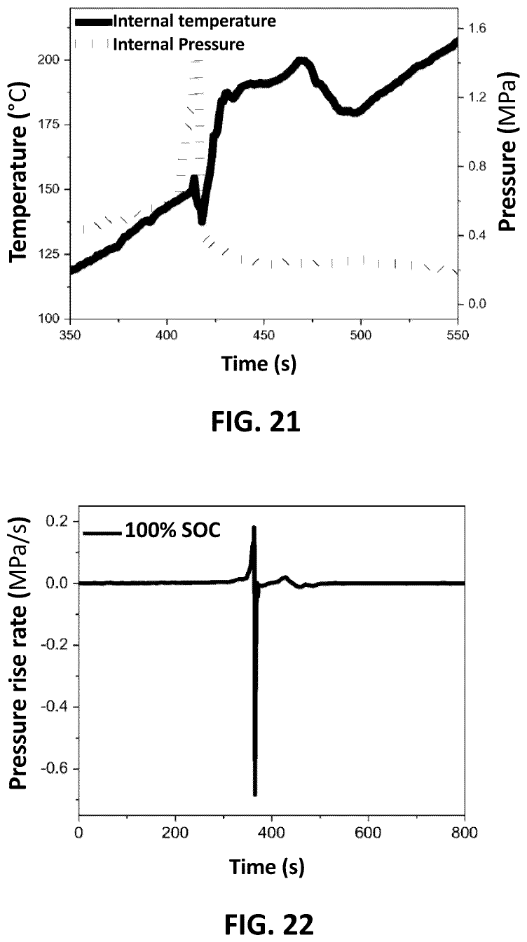

FIG. 21 depicts the analysis curve of the internal short-circuit state for a 0% charged battery in an embodiment of the present disclosure, specifically using a lithium iron phosphate/graphite cylindrical 18650 single cell with a rated capacity of 1530 mAh as an example. The second warning represents the critical value indicating that the battery is about to enter an internal short-circuit state. Commercially available polyethylene (PP) and polypropylene (PE) separator materials used internally in energy storage devices have melting points of approximately 165° C. and 135° C. respectively. As the temperature continues to rise, exceeding the melting point of the separator will lead to its shrinkage and decomposition, allowing the positive and negative electrode materials to come into contact with each other, resulting in an internal short-circuit. Due to the formation of the internal short-circuit, a rapid temperature rise is detected within the energy storage device, manifesting as a sudden temperature increase of approximately 45° C. The pressure gradually rises to 1.65 MPa, and then the battery safety valve opens, causing the pressure to drop instantaneously to 0.1 MPa. By simultaneously acquiring the change information of both internal temperature and internal pressure, analyzing the correlation between temperature and pressure, and conducting a comprehensive analysis, the internal short-circuit state of the battery determined by the second warning can be precisely identified.

The safety valve opening state (i.e. the state where the safety valve is opened) can be used to determine and trigger the second warning. The conditions for the safety valve opening warning are: the internal pressure is greater than U; and the rate of pressure change is V. Both U and V are determined based on the type of battery and its different charging states. For instance, in a lithium iron phosphate/graphite cylindrical 18650 single cell with a rated capacity of 1530 mAh, U is set at 1.5 MPa, and Vis set at a rate less than −0.1 MPa/s or greater than 0.1 MPa/s. The following will provide an explanation using specific embodiments.

FIG. 22 presents the analysis curve of the safety valve opening state for a 100% charged battery in an embodiment of the present disclosure. Specifically, the safety valve opening state can be used to determine the second warning. Taking a lithium iron phosphate/graphite cylindrical 18650 single cell with a rated capacity of 1530 mAh as an example, an optical sensor is implanted inside the battery, and a heating rod with a rated power of 100 W is used to thermally abuse the battery. As shown in FIGS. 9 and 19, as the battery is exposed to continuous external heat sources combined with the heat generated by internal short-circuits, more and more gas is produced inside the battery, causing the internal pressure to rapidly increase to 1.79 MPa. During this process, the rate of pressure change ranges from approximately −0.7 Mpa/s to 0.2 Mpa/s until the pressure exceeds the threshold of the battery's safety valve, leading to the occurrence of safe venting. The released gas includes electrolyte vapor and gases produced by side reactions. Since traditional pressure detection equipment cannot be implanted inside the battery to provide early warning for battery gas release, the rate of internal pressure change measured by the optical sensor inside the battery can be used as early warning information for the thermal runaway safety valve opening state of the battery.

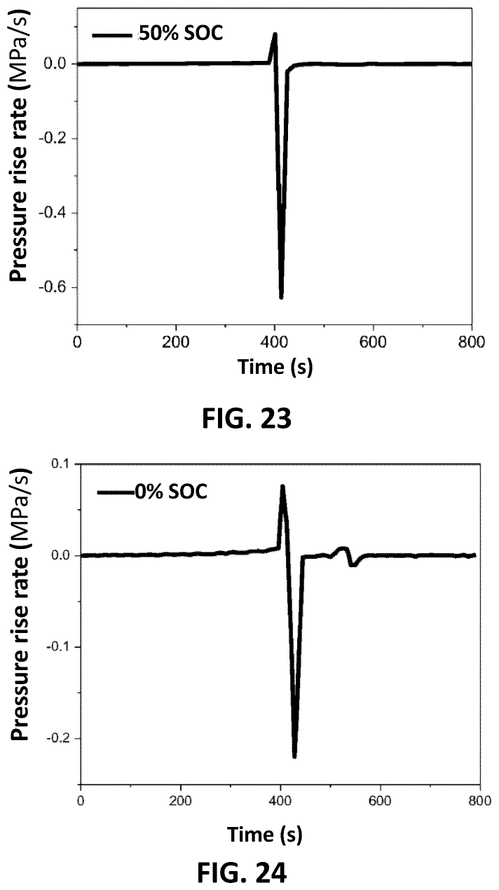

FIG. 23 depicts the analysis curve of the safety valve opening state for a 50% charged battery in an embodiment of the present disclosure. Specifically, the safety valve opening state can be used to determine the second warning. Taking a lithium iron phosphate/graphite cylindrical 18650 single cell with a rated capacity of 1530 mAh as an example, an optical sensor is implanted inside the battery, and a heating rod with a rated power of 100 W is used to thermally abuse the battery. As shown in FIGS. 10 and 20, as the battery is exposed to continuous external heat sources combined with the heat generated by internal short-circuits, more and more gas is produced inside the battery, causing the internal pressure to rapidly increase to 1.66 MPa. During this process, the rate of pressure change ranges from approximately −0.65 MPa/s to 0.1 MPa/s until the pressure exceeds the threshold of the battery's safety valve, leading to the occurrence of safe venting. The released gas includes electrolyte vapor and gases produced by side reactions. Since traditional pressure detection equipment cannot be implanted inside the battery to provide early warning for battery gas release, the rate of internal pressure change measured by the optical sensor inside the battery can be used as early warning information for the thermal runaway safety valve opening state of the battery.

FIG. 24 presents the analysis curve of the safety valve opening state for a 0% charged battery in an embodiment of this disclosure. Specifically, the safety valve opening state can be used to determine the second warning. Taking a lithium iron phosphate/graphite cylindrical 18650 single cell with a rated capacity of 1530 mAh as an example, an optical sensor is implanted inside the battery, and a heating rod with a rated power of 100 W is used to thermally abuse the battery. As shown in FIGS. 11 and 21, as the battery is exposed to continuous external heat sources combined with the heat generated by internal short-circuits, more and more gas is produced inside the battery, causing the internal pressure to rapidly increase to 1.65 MPa. During this process, the rate of pressure change ranges from approximately −0.25 MPa/s to 0.1 MPa/s until the pressure exceeds the threshold of the battery's safety valve, leading to the occurrence of safe venting. The released gas includes electrolyte vapor and gases produced by side reactions. Since traditional pressure detection equipment cannot be implanted inside the battery to provide early warning for battery gas release, the rate of internal pressure change measured by the optical sensor inside the battery can be used as early warning information for the thermal runaway safety valve opening state of the battery.

In one possible embodiment, the third warning judgment is as follows: when the internal temperature rise rate is equal to or greater than 1° C./s and the pressure value is greater than 0.1 MPa, the appearance of a “wave packet” with the pressure rising first and then falling indicates the start of thermal runaway. When the internal temperature reaches the maximum temperature and the pressure is atmospheric pressure (0.1 MPa), it indicates the end of thermal runaway.

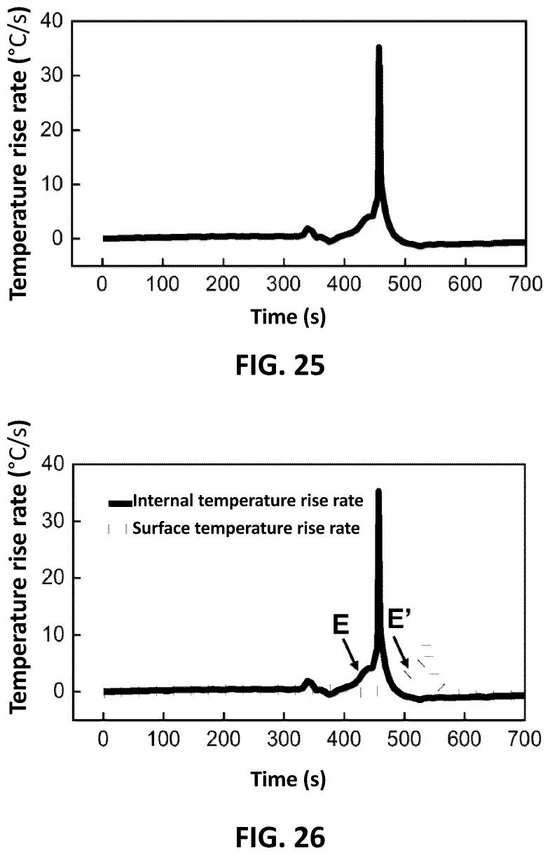

FIG. 25 shows the thermal runaway state analysis curve for the energy storage device in an embodiment of the present disclosure. Specifically, the thermal runaway state corresponds to the third warning. Taking the energy storage device 20 as an example, it consists of a lithium iron phosphate/graphite cylindrical 18650 single cell with a rated capacity of 1530 mAh, where the single cell is in a 100% charged state. An optical sensor is implanted inside the battery, and a heating rod with a rated power of 100 W is used to thermally abuse and simulate the battery to trigger thermal runaway. As the battery is exposed to continuous external heat sources, the reaction between the electrodes and electrolyte, as well as the reaction between the graphite electrode and binder, accelerate the occurrence of thermal runaway in the battery. When the temperature of thermal runaway continues to rise (reaching a rise rate of 5° C./s), it is determined that the thermal runaway state of the battery has been triggered. Among them, point A serves as the starting point (around 420 s) for triggering the thermal runaway state of the battery. According to FIG. 9, the internal temperature of the battery reaches around 200° C. at this moment. From then on, the rate of temperature increase inside the battery gradually increases to 35° C./s, and the battery starts to emit intense smoke. According to FIG. 9, the internal temperature reaches its peak of 510° C., and after the completion of thermal runaway, the battery temperature begins to decline. Therefore, the rate of internal temperature change measured by the optical sensor inside the energy storage device can be used as early warning information for the thermal runaway state of the energy storage device.

FIG. 26 depicts the internal and external temperature alteration curves of an energy storage device under thermal runaway conditions in an embodiment of the present disclosure. Taking the energy storage device 20 as an example, it consists of a lithium iron phosphate/graphite cylindrical 18650 single cell with a rated capacity of 1530 mAh. An optical sensor is implanted inside the battery, and a heating rod with a rated power of 100 W is used to thermally abuse and simulate the battery to trigger thermal runaway. As the battery is exposed to continuous external heat sources, the reaction between the electrodes and electrolyte, as well as the reaction between the graphite electrode and binder, accelerate the occurrence of thermal runaway in the battery. When the temperature rise rate of thermal runaway in the battery reaches 5° C./s, it is determined that the thermal runaway state of the battery has been triggered. Around 420 s (point E), the internal temperature rise rate of the battery reaches 5° C./s, with the internal temperature reaching approximately 200° C. However, the surface temperature rise rate is only 0.5° C./s. After that, the internal temperature rise rate of the battery gradually increases to 35° C./s, resulting in intense smoking and an internal temperature peak of 510° C. However, when the surface temperature rise rate of the battery reaches 5° C./s, it occurs around 520 s (point E′). Therefore, compared to external traditional temperature sensors, the optical sensor inside the battery can detect abnormal battery temperatures 100 s earlier, providing a new warning technology for preventing battery thermal runaway.

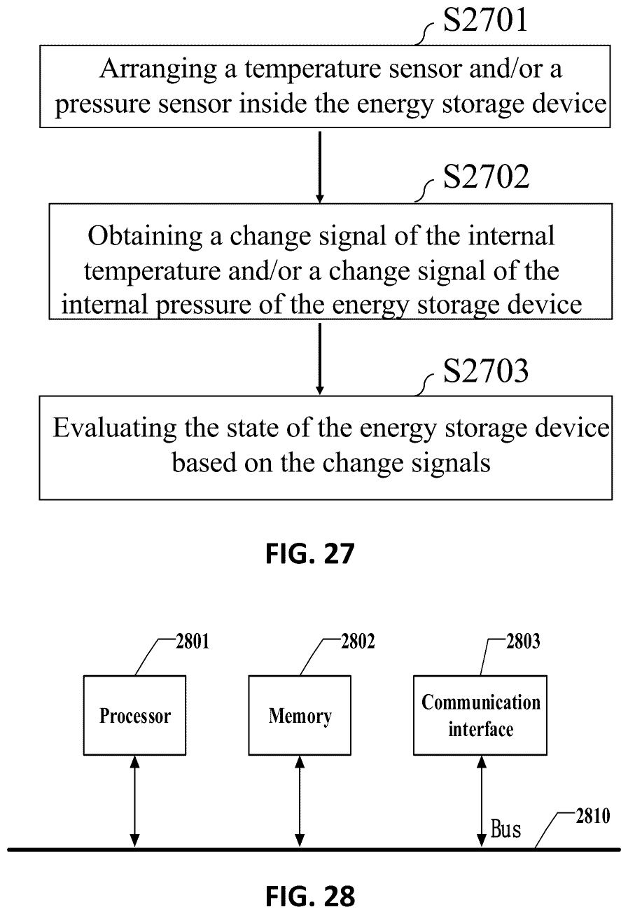

FIG. 27 depicts the flowchart of the internal temperature and pressure detection method for an energy storage device provided in an embodiment of the present disclosure. Specifically, the detection method comprises the following steps:
S2701. Arranging a temperature sensor and/or a pressure sensor inside the energy storage device.
S2702. Obtaining a change signal of the internal temperature and/or a change signal of the internal pressure of the energy storage device.
S2703. Evaluating the state of the energy storage device based on the change signals.

Herein, the temperature sensor and the pressure sensor can be implemented by the sensing module 30 of the energy storage device detection device as depicted in FIG. 5 and described above.

Herein, the change signals include at least one of a numerical relationship of temperature, a numerical relationship of pressure, a derivative relationship of temperature, a derivative relationship of pressure, a derivative relationship between temperature and pressure, and an integral relationship between temperature and pressure. These change signals are used to evaluate the safety state of the energy storage device 20 and to trigger first, second, and/or third warnings. Specifically, the first warning is used to determine an irreversible state of the energy storage device 20; the second warning is used to determine an internal short circuit and/or a safety valve opening state in the energy storage device 20; and the third warning is used to determine a thermal runaway state of the energy storage device 20.

According to some embodiments, the method may further include: acquiring the spectral signal corresponding to the change signal; performing intensity alteration analysis, wavelength alteration analysis, envelope alteration analysis, differential analysis, and integral analysis on the spectral signal; and establishing an optical correlation between parameters related to the safety performance of the energy storage device.

FIG. 28 shows a schematic diagram of the hardware structure of the energy storage system detection system provided by the present disclosure.

The energy storage system detection system can include a processor 2801 and a memory 2802 that stores computer program instructions.

Specifically, the processor 2801 mentioned above can include a CPU or an Application Specific Integrated Circuit (ASIC), or can be configured to implement one or more integrated circuits of the embodiments disclosed herein.

The memory 2802 may include high-capacity storage for data or instructions. For example, but not limited to, the memory 2802 can include a hard disk drive (HDD), floppy disk drive, flash memory, optical disc, magneto-optical disc, magnetic tape, or Universal Serial Bus (USB) drive, or a combination of two or more of these. In appropriate cases, the memory 2802 may include removable or non-removable (or fixed) media. In suitable situations, the memory 2802 may be internal or external to a comprehensive gateway disaster recovery device. In certain embodiments, the memory 2802 is non-volatile solid-state memory.

The memory 2802 may include read-only memory (ROM), random-access memory (RAM), disk storage media devices, optical storage media devices, flash memory devices, electrical, optical, or other physical/tangible storage memory devices. Therefore, generally speaking, memory 2802 comprises one or more tangible (non-transitory) computer-readable storage media (such as memory devices) encoded with software that includes computer-executable instructions, and when the software is executed (for example, by one or more processors), it is operable to perform the operations described with reference to the methods according to an aspect of the present disclosure.

The processor 2801 reads and executes the computer program instructions stored in the memory 2802 to achieve any one of the energy storage device detection methods described in the above embodiments.

In an example, the energy storage system detection system may further include a communication interface 2803 and a bus 2810. As shown in FIG. 28, the processor 2801, memory 2802, and communication interface 2803 are connected via the bus 2810 to facilitate communication between them.

The communication interface 2803 is primarily used to enable communication between various modules, devices, units, and/or equipment in the embodiments disclosed herein.

The bus 2810 includes hardware, software, or a combination of both that interconnects the components of the device. For example, but not limited to, the bus may include an Accelerated Graphics Port (AGP) or other graphics bus, Enhanced Industry Standard Architecture (EISA) bus, Front Side Bus (FSB), Hyper Transport (HT) interconnect, Industry Standard Architecture (ISA) bus, InfiniBand interconnect, Low Pin Count (LPC) bus, Memory bus, Micro Channel Architecture (MCA) bus, Peripheral Component Interconnect (PCI) bus, PCI-Express (PCI-X) bus, Serial Advanced Technology Attachment (SATA) bus, Video Electronics Standards Association Local (VLB) bus, or a suitable combination of two or more of these. In appropriate cases, the bus 2810 may include one or more buses. Although specific buses are described and depicted in the embodiments disclosed herein, any suitable bus or interconnect is considered within the scope of the present disclosure.

Furthermore, in conjunction with the energy storage system detection methods described in the above embodiments, the present disclosure provides a computer-readable storage medium. The computer-readable storage medium stores computer program instructions that, when executed by a processor, implement any of the energy storage system detection methods disclosed herein.

Those skilled in the art will appreciate that, for the sake of convenience and brevity, the specific operational processes of the described methods can refer to corresponding processes in the previous system embodiments and are not further elaborated here.

The foregoing is merely a specific embodiment of the present disclosure, but the scope of the present disclosure is not limited thereto. Those skilled in the art will readily conceive various equivalent modifications or substitutions within the technical scope disclosed in the present disclosure, which should be encompassed within the scope of the present disclosure. Therefore, the protection scope of the present disclosure shall be determined by the claims.

1. A method for detecting a state of an energy storage device, comprising:
acquiring at least one of a change signal of a temperature or a change signal of a pressure inside the energy storage device; and
determining the state of the energy storage device based on the at least one of the change signal of the temperature or the change signal of the pressure.

2. The method of claim 1, wherein:
the change signal of the temperature comprises at least one of a numerical relationship of the temperature, a derivative relationship of the temperature, or a derivative relationship between the temperature and the pressure; and
the change signal of the pressure comprises at least one of a numerical relationship of the pressure, a derivative relationship of the pressure, or a derivative relationship between the temperature and the pressure.

3. The method of claim 1, further comprising:
triggering a warning when the state of the energy storage device meets a preset condition.

4. The method of claim 3, wherein the warning comprises a first warning, configured to be triggered when the energy storage device is determined to be in an irreversible state.

5. The method of claim 4, wherein the energy storage device comprises a battery, and the irreversible state comprises at least one of solid electrolyte interface (SEI) decomposition, separator melting, electrode-electrolyte reaction, electrode-binder reaction, or electrolyte decomposition.

6. The method of claim 4, wherein the first warning is determined based on at least one of a derivative relationship of the temperature or a derivative relationship of the pressure.

7. The method of claim 6, wherein the first warning is determined based on at least one of the occurrence of an inflection point in a derivative of the temperature or the occurrence of an inflection point in a derivative of the pressure.

8. The method of claim 3, wherein the warning further comprises a second warning, configured to be triggered when the energy storage device is determined to be in an internal short circuit state and/or a safety valve opening state.

9. The method of claim 8, wherein the internal short circuit state comprises at least one of separator melting, contact between positive and negative electrodes, or voltage drop; and the safety valve opening state comprises at least one of gas release, pressure increase, or mass loss.

10. The method of claim 8, wherein the second warning is triggered when at least one of the following is met:
the temperature suddenly jumps; or the pressure suddenly drops after reaching a maximum value.

11. The method of claim 3, wherein the warning further comprises a third warning, configured to be triggered when the energy storage device is determined to be in a thermal runaway state.

12. The method of claim 11, wherein the thermal runaway state comprises at least one of continuous temperature rise, gas release, the emergence of a second pressure peak, combustion, or explosion.

13. The method of claim 11, wherein the third warning is triggered when the temperature continues to rise while the pressure first increases and then decreases.

14. The method of claim 1, wherein the method is by means of a detection device, wherein the detection device comprises a sensing module and an analyzing module, wherein:
the acquiring at least one of a change signal of a temperature or a change signal of a pressure inside the energy storage device is by means of the sensing model; and
the determining the state of the energy storage device is by means of the analyzing module.

15. The method of claim 14, wherein the sensing module comprises at least one of an optical sensor or an electrical sensor.

16. The method of claim 15, wherein:
the optical sensor comprises an optical chip and/or a fiber sensor, wherein the fiber sensor comprises one or more of a tilted fiber Bragg grating, a fiber Bragg grating, a long-period fiber grating, a fiber core diameter mismatch device, a fiber core misalignment device, a tapered fiber device, a micro/nano fiber device, a Fabry-Perot fiber device, a single/multi-mode fiber structure device, a photonic crystal fiber device, a microstructure fiber device, a polymer fiber device, a sapphire optical device, a fiber laser device, a fiber coupling device, or a self-assembled optical device; and
the electrical sensor comprises one or more of a thermistor, a thermocouple, a thermal capacitor, a nano temperature sensor, an infrared temperature sensor, a piezoresistive sensor, a piezoelectric sensor, a piezoelectric ceramic sensor, a piezoelectric acoustic wave sensor, a piezoelectric resonance sensor, a pressure wire sensor, or a capacitive sensor.

17. The method of claim 16, wherein the fiber sensor comprises a fiber Bragg grating and a Fabry-Perot fiber device.

18. The method of claim 14, wherein the sensing module is arranged at an interior position of the energy storage device, wherein the interior position comprises one or more of an internal gap position, an electrode position, a separator position, an electrolyte position, and a tab position; wherein the internal gap position comprises one or more of a cell hole position, a cell top cover position, and a cell shell inner side position.

19. The method of claim 1, wherein the energy storage device comprises a lithium-ion battery, a solid-state battery, a lithium metal battery, a lithium-sulfur battery, a lithium-air battery, a sodium-ion battery, a zinc-ion battery, an aluminum-ion battery, a magnesium-ion battery, a potassium-ion battery, a sodium-sulfur battery, a flow battery, a liquid metal battery, a metal-air battery, a lead-acid battery, a fuel cell, a solar cell, or a supercapacitor.

20. The method of claim 1, wherein the state of the energy storage device comprises at least one of a state of health (SOH), a state of charge (SOC), or a safety lifespan.
